(19) United States
(12) Patent Application Publication
(10) Pub. No.: US 2026/0293260 A1
(43) Pub. Date: Sep. 24, 2026

(54) SEMICONDUCTOR DEVICE INCLUDING ISOLATION INSULATING FILM AND SOURCE/DRAIN CONTACT

(71) Applicant: Samsung Electronics Co., Ltd., Suwon-si (KR)

(72) Inventors: Won Hyuk Lee, Suwon-si (KR); Jeong Yeon Seo, Suwon-si (KR); Yoo Sub Shin, Suwon-si (KR); Sang Eun Yun, Suwon-si (KR); Ji-Eun Han, Suwon-si (KR)

(73) Assignee: Samsung Electronics Co., Ltd., Suwon-si (KR)

(21) Appl. No.: 19/571,417

(22) Filed: Mar. 18, 2026

(30) Foreign Application Priority Data
Mar. 19, 2025 (KR) 10-2025-0035533

(51) Int. Cl. H10D 64/23; H10D 30/00; H10D 64/01

(52) U.S. Cl. CPC H10D 64/251; H10D 30/501; H10D 64/0111

(57) ABSTRACT

A semiconductor device includes active patterns extending in a first direction and spaced apart from one another in a second direction; a gate electrode on the active patterns and extending in the second direction; a source/drain pattern on at least one side of the gate electrode; a source/drain contact on the source/drain pattern; an isolation insulating film on the gate electrode and the source/drain contact; and a source/drain via in the isolation insulating film and on the source/drain contact, wherein the isolation insulating film includes a first film and a second film on the first film, wherein the first film and the second film include different materials, and wherein the first film extends along and on a bottom surface and a lower portion of a sidewall of the second film, and does not extend along and on an upper portion of the sidewall of the second film.

### CROSS-REFERENCE TO RELATED APPLICATIONS

This present application claims priority to and the benefit under 35 U.S.C. § 119(a)-(d) of Korean Patent Application No. 10-2025-0035533 filed on Mar. 19, 2025 in the Korean Intellectual Property Office, the entire disclosure of which is incorporated herein by reference.

### FIELD

The present disclosure relates to a semiconductor device and more particularly to a semiconductor device including an isolation insulating film and a source/drain contact, and to a method for manufacturing a semiconductor device.

### BACKGROUND

One of scaling schemes for increasing an integration density of a semiconductor device proposes a multi-gate transistor in which a multi-channel active pattern (or a silicon body) in a shape of a fin or a nanowire is formed on a substrate, and a gate is formed on a surface of the multi-channel active pattern.

Because such a multi-gate transistor uses a three-dimensional channel, it is easy to scale the same. Further, current control capability of the multi-gate transistor may be improved without increasing a gate length of the multi-gate transistor. In addition, the multi-gate transistor may effectively suppress SCE (short channel effect) in which potential of a channel area is affected by drain voltage.

### SUMMARY

According to aspects of the present disclosure, there is provided a semiconductor device including active patterns extending in a first direction and spaced apart from one another in a second direction; a gate electrode on the active patterns and extending in the second direction; a source/drain pattern on at least one side of the gate electrode; a source/drain contact on the source/drain pattern; an isolation insulating film on the gate electrode and the source/drain contact; and a source/drain via in the isolation insulating film and on the source/drain contact, wherein the isolation insulating film includes a first film and a second film on the first film, wherein the first film and the second film include different materials, and wherein the first film extends along and on a bottom surface and a lower portion of a sidewall of the second film, and does not extend along and on an upper portion of the sidewall of the second film.

According to embodiments of the present disclosure, there is provided a semiconductor device including active patterns extending in a first direction and spaced apart from one another in a second direction; a gate electrode on the active patterns and extending in the second direction; a source/drain pattern on at least one side of the gate electrode; a source/drain contact on the source/drain pattern; an isolation insulating film on the gate electrode and the source/drain contact; and a source/drain via in the isolation insulating film and on the source/drain contact, wherein the isolation insulating film is partially intruded into the source/drain contact.

According to embodiments of the present disclosure, there is provided a semiconductor device including active patterns extending in a first direction and spaced apart from one another in a second direction; a gate electrode on the active pattern and extending in the second direction; a source/drain pattern on at least one side of the gate electrode; a source/drain contact on the source/drain pattern; an isolation insulating film on the gate electrode and the source/drain contact; a source/drain via in the isolation insulating film and on the source/drain contact; and a gate via in the isolation insulating film and on the gate electrode, wherein the isolation insulating film includes a first film and a second film disposed on the first film, wherein at least a portion of a bottom surface of the source/drain via and at least a portion of a bottom surface of the gate via are in contact with the first film.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is an example layout diagram for illustrating a semiconductor device according to some embodiments;

FIG. 2 is a cross-sectional view taken along a line A-A′ of FIG. 1;

FIG. 3 is a cross-sectional view taken along a line B-B′ of FIG. 1;

FIG. 4 is a cross-sectional view taken along a line C-C′ of FIG. 1;

FIG. 5 is a cross-sectional view taken along a line D-D′ of FIG. 1;

FIGS. 6 to 33 are diagrams of intermediate structures corresponding to intermediate steps of a method for manufacturing a semiconductor device according to some embodiments;

FIGS. 34 to 37 are diagrams for illustrating a semiconductor device according to some embodiments;

FIGS. 38 and 39 are diagrams of intermediate structures corresponding to intermediate steps of a method for manufacturing a semiconductor device according to some embodiments;

FIGS. 40 and 41 are diagrams for illustrating a semiconductor device according to some embodiments;

FIG. 42 is an example layout diagram for illustrating a semiconductor device according to some embodiments;

FIG. 43 is a cross-sectional view taken along a line A-A′ of FIG. 42;

FIG. 44 is a cross-sectional view taken along a line B-B′ of FIG. 42;

FIG. 45 is a cross-sectional view taken along a line C-C′ of FIG. 42; and

FIG. 46 is a cross-sectional view taken along a line D-D′ of FIG. 42.

### DETAILED DESCRIPTION

Although the first, second, and the like are used herein to describe various elements or components, it is obvious that these elements or components are not limited by these terms. These terms are merely used to distinguish one element or component from another element or component. Accordingly, it is obvious that the first element or component as mentioned below may be the second element or component within the technical idea of the present disclosure.

In the drawings of the semiconductor device according to some embodiments, a fin-type transistor (FinFET) including a channel area having a fin pattern shape, a transistor including a nanowire or a nanosheet, and MBCFET™ (Multi-Bridge Channel Field Effect Transistor) are illustrated. However, embodiments of the present disclosure are not limited thereto. The semiconductor device according to some embodiments may include a tunneling FET or a three-dimensional (3D) transistor. The semiconductor device according to some embodiments may include a planar transistor. In addition, the technical idea of the present disclosure may be applied to a transistor (2D material based FETs) based on a two-dimensional material and a heterostructure thereof.

Further, the semiconductor device according to some embodiments may include a bipolar junction transistor, a LDMOS (lateral double diffused metal oxide semiconductor) transistor, and the like.

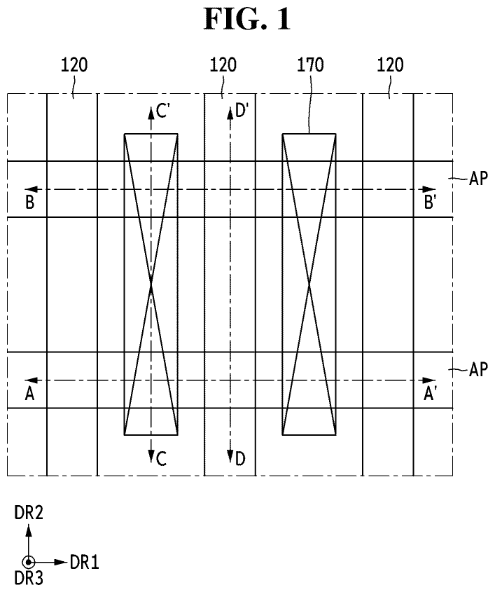

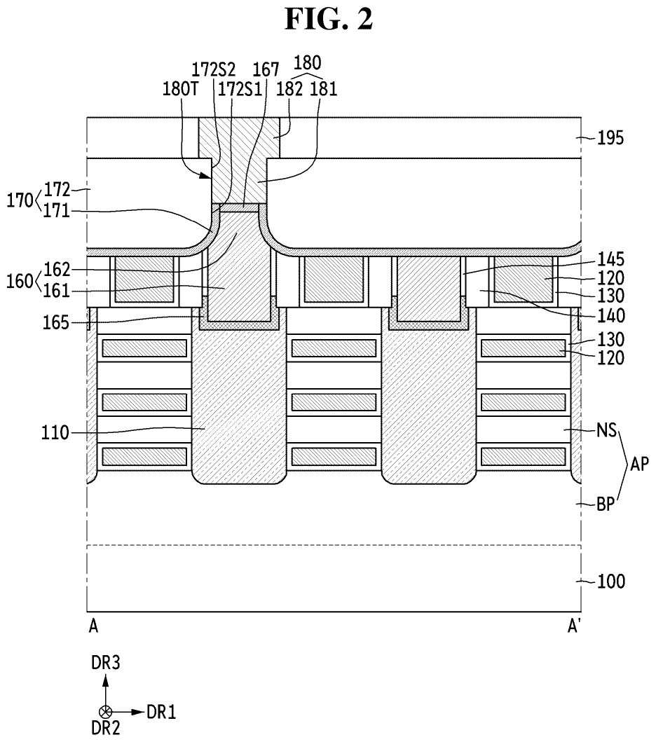

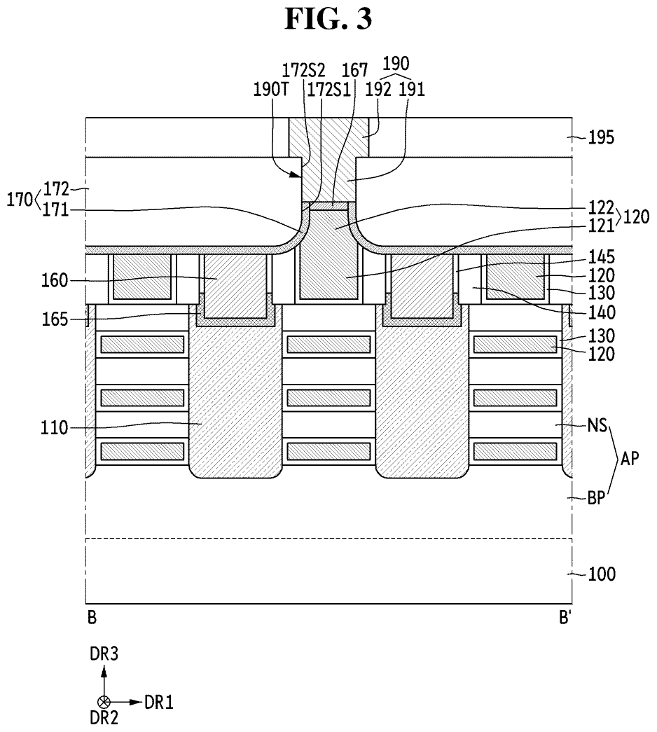

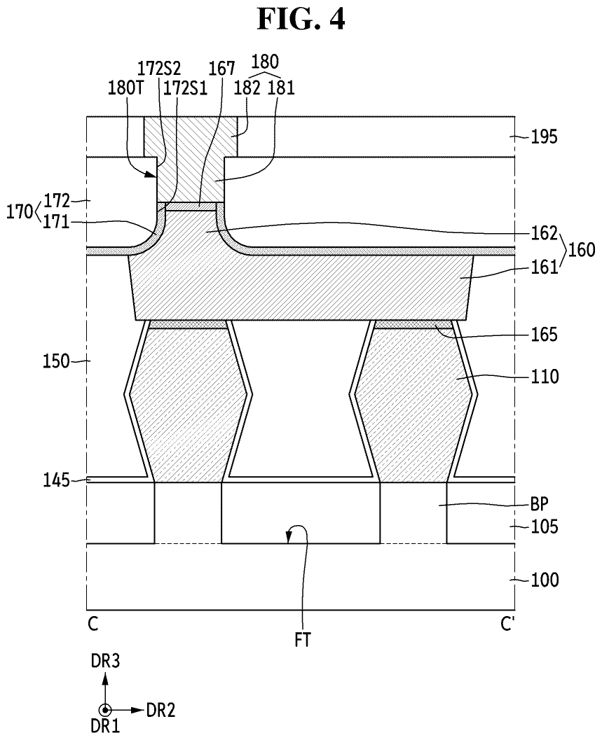

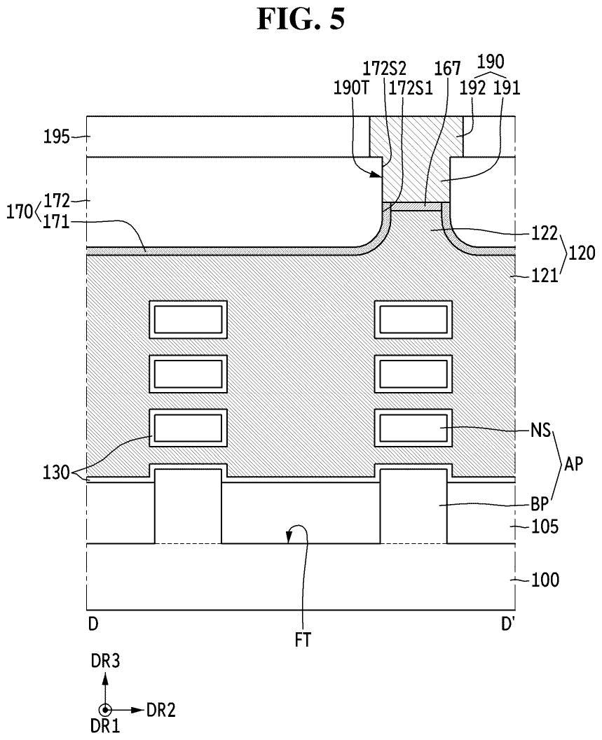

FIG. 1 is an example layout diagram for illustrating a semiconductor device according to some embodiments. FIG. 2 is a cross-sectional view taken along a line A-A′ of FIG. 1. FIG. 3 is a cross-sectional view taken along a line B-B′ of FIG. 1. FIG. 4 is a cross-sectional view taken along a line C-C′ of FIG. 1. FIG. 5 is a cross-sectional view taken along a line D-D′ of FIG. 1.

For convenience of illustration, the source/drain via 180 and the gate via 190 are not illustrated in FIG. 1. In addition, although it is illustrated that the gate via 190 is disposed on one gate electrode 120 among the plurality of gate electrodes 120 and the source/drain via 180 is disposed on one source/drain contact 160 among the plurality of source/drain contacts 160, this is only for explanation and embodiments of the present disclosure are not limited thereto.

Referring to FIGS. 1 to 4, the semiconductor device according to some embodiments may include an active pattern AP, a source/drain pattern 110, a gate electrode 120, a source/drain contact 160, a conductive film 167, an isolation insulating film 170, a source/drain via 180, and a gate via 190.

For example, the substrate 100 may be made of bulk silicon or silicon-on-insulator (SOI). Alternatively, the substrate 100 may be a silicon substrate, or may include a material other than silicon, for example, silicon germanium, silicon germanium on insulator (SGOI), indium antimonide, lead telluride compound, indium arsenide, indium phosphide, gallium arsenide, or gallium antimonide. However, embodiments of the present disclosure are not limited thereto. In another example, the substrate 100 may be made of an insulating material.

The active pattern AP may be disposed on the substrate 100. Each of the active patterns AP may extend in a first direction DR1. The active patterns AP may be spaced apart from one another in a second direction DR2. For example, the first direction DR1 is a direction intersecting the second direction DR2.

For example, the active pattern AP may be an area in which a PMOS is formed or an area in which a NMOS is formed. In another example, a portion of the active pattern AP may be a PMOS formation area, and the rest thereof may be a NMOS area.

For example, the active pattern AP may be disposed in a logic area. In another example, the active pattern AP may be disposed in a SRAM area. In still another example, the active pattern AP may be disposed in an I/O area.

The active pattern AP may be, for example, a multi-channel active pattern. The active pattern AP may include a lower pattern BP and a plurality of sheet patterns NS. The lower pattern BP may protrude from the substrate 100. The lower pattern BP may extend in an elongate manner in the first direction DR1. The lower patterns BP may be spaced apart from one another in the second direction DR2. The lower patterns BP may be isolated from one another via a fin trench FT extending in the first direction DR1.

The plurality of sheet patterns NS may be disposed on an upper surface of the lower pattern BP. The sheet patterns NS may be spaced apart from the lower pattern BP in a third direction DR3. The sheet patterns NS may be spaced apart from one another in the third direction DR3. The third direction DR3 may be a direction intersecting the first direction DR1 and the second direction DR2. For example, the third direction DR3 may be a thickness direction of the substrate 100. Although it is illustrated that three sheet patterns NS are arranged in the third direction DR3, this is intended only for convenience of illustration and embodiments of the present disclosure are not limited thereto.

For example, the lower pattern BP may be formed by etching a portion of the substrate 100 or may include an epitaxial layer grown from the substrate 100. Each of the lower patterns BP may include silicon or germanium, which is an elemental semiconductor material. In addition, the lower pattern BP may include a compound semiconductor, for example, a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto.

The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with one another, a ternary compound obtained by combining two of aluminum (Al), gallium (Ga), and indium (In) as a group III element and one of phosphorus (P), arsenic (As), and antimony (Sb) as a group V with one another, or a quaternary compound obtained by combining three of aluminum (Al), gallium (Ga), and indium (In) as a group III element and one of phosphorus (P), arsenic (As), and antimony (Sb) as a group V with one another.

In another example, the lower pattern BP may be formed by filling a space obtained by removing a pattern including a semiconductor material with an insulating material. The lower pattern BP may include an insulating material.

The sheet pattern NS may include one of silicon or germanium as an element semiconductor material, a group IV-IV compound semiconductor, or a group III-V compound semiconductor. When the lower pattern BP includes a semiconductor material, the sheet pattern NS may include the same material as the material of the lower pattern BP, or may include a material different from the material of the lower pattern BP. In the semiconductor device according to some embodiments, the lower pattern BP may be a silicon lower pattern including silicon, and the sheet pattern NS may be a silicon sheet pattern including silicon.

For example, a width of the sheet pattern NS in the second direction DR2 may increase or decrease in proportion to a width of the lower pattern BP in the second direction DR2. For example, although it is illustrated that the widths in the second direction DR2 of the sheet patterns NS stacked in the third direction DR3 are equal to one another, this is intended only for convenience of illustration, and embodiments of the present disclosure are not limited thereto. Unlike the illustrated example, as vertical levels of the sheet patterns NS based on the lower pattern BP increases, the widths in the second direction D2 of the sheet patterns NS stacked in the third direction D3 may decrease. That is, a width in the second direction D2 of the topmost sheet patterns NS may be the smallest.

The field insulating film 105 may be formed on the substrate 100. The field insulating film 105 may fill at least a portion of the fin trench FT.

The field insulating film 105 may be disposed on a sidewall of the lower pattern BP. The field insulating film 105 is not disposed on an upper surface of the lower pattern BP. For example, the field insulating film 105 may entirely cover the sidewall of the lower pattern BP. Unlike the illustrated example, the field insulating film 105 may cover a portion of a sidewall of the lower pattern BP. In this case, a portion of the lower pattern BP may protrude in the third direction DR3 beyond an upper surface of the field insulating film 105.

A vertical level of each of the sheet patterns NS is higher than that of the upper surface of the field insulating film 105. The field insulating film 105 may include, for example, an oxide film, a nitride film, an oxynitride film, or a combination thereof. Although the field insulating film 105 is illustrated as being embodied as a single film, this is intended only for convenience of illustration and embodiments of the present disclosure are not limited thereto.

The gate electrode 120 may be disposed on the substrate 100. For example, the gate electrode 120 may be disposed on the field insulating film 105. The gate electrode 120 may extend in the second direction DR2. The gate electrodes 120 may be spaced apart from one another in the first direction DR1.

The gate electrode 120 may be disposed on the active pattern AP. The gate electrode 120 may intersect the active pattern AP. Although the gate electrode 120 is illustrated as being disposed across the plurality of active patterns AP, this is intended only for convenience of illustration, and embodiments of the present disclosure are not limited thereto. That is, the at least one gate electrode 120 may be divided into two portions which may be disposed on different active patterns AP, respectively.

The gate electrode 120 may be disposed on the lower pattern BP. The gate electrode 120 may intersect the lower pattern BP. The gate electrode 120 may surround the sheet pattern NS. The gate electrode 120 may be disposed between the sheet patterns NS adjacent to one another in the third direction DR3.

The gate electrode 120 may include a first portion 121 and a second portion 122. The first portion 121 may be disposed on the active pattern AP and the field insulating film 105. The first portion 121 may surround the sheet pattern NS. The first portion 121 may be disposed between the sheet patterns NS adjacent to one another in the third direction DR3. The second portion 122 may be disposed on the first portion 121.

The first portion 121 may extend in the second direction DR2. The second portion 122 may protrude from the first portion 121 in the third direction DR3. A width in the second direction DR2 of the first portion 121 may be greater than a width in the second direction DR2 of the second portion 122. A width in the first direction DR1 of the first portion 121 may be equal to a width in the first direction DR1 of the second portion 122. For example, the second portion 122 may overlap the active pattern AP in the third direction DR3. However, embodiments of the present disclosure are not limited thereto. For example, the second portion 122 may overlap the field insulating film 105 in the third direction DR3.

The gate electrode 120 may include at least one of a metal, a metal alloy, a conductive metal nitride, a metal silicide, a doped semiconductor material, a conductive metal carbonitride, a conductive metal carbide, a conductive metal oxide, or a conductive metal oxynitride. The gate electrode 120 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. However, embodiments of the present disclosure are not limited thereto. The conductive metal oxide and the conductive metal oxynitride may include oxidized products of the above-mentioned materials. However, embodiments of the present disclosure are not limited thereto.

The gate insulating film 130 may extend along and on the upper surface of the field insulating film 105 and the upper surface of the lower pattern BP. The gate insulating film 130 may surround the sheet pattern NS. The gate insulating film 130 may be disposed along the circumference of the sheet pattern NS. The gate electrode 120 is disposed on the gate insulating film 130. The gate insulating film 130 may be disposed between the gate electrode 120 and the sheet pattern NS.

The gate insulating film 130 may include silicon oxide, silicon oxynitride, silicon nitride, or a high-k material having a dielectric constant greater than that of silicon oxide. The high dielectric constant (high-k) material may include at least one of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

Although the gate insulating film 130 is illustrated as being a single film, it is intended only for convenience of illustration and embodiments of the present disclosure are not limited thereto. The gate insulating film 130 may include a plurality of films. The gate insulating film 130 may include an interfacial film disposed between the sheet pattern NS and the gate electrode 120, and a high dielectric constant insulating film.

The semiconductor device according to some embodiments may include an NC (negative capacitance) FET using a negative capacitor. For example, the gate insulating film 130 may include a ferroelectric material film having ferroelectric properties and a paraelectric material film having paraelectric properties.

The ferroelectric material film may have negative capacitance, and the paraelectric material film may have positive capacitance. For example, when two or more capacitors may be connected in series to one another, and capacitance of each of the capacitors has a positive value, a total capacitance is smaller than capacitance of each individual capacitor. On the contrary, when at least one of capacitances of two or more capacitors connected in series to one another has a negative value, a total capacitance may have a positive value and be greater than an absolute value of each individual capacitance.

When the ferroelectric material film with negative capacitance and the paraelectric material film with positive capacitance are connected in series to one another, a total capacitance value of the ferroelectric material film and the paraelectric material film connected in series to one another may be increased. Using the increase in the total capacitance value, a transistor including the ferroelectric material film may have a subthreshold swing (SS) lower than about 60 m V/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

11

When the ferroelectric material film includes hafnium oxide, the dopant contained in the ferroelectric material film may include, for example, at least one of gadolinium (Gd), silicon (Si), zirconium (Zr), aluminum (Al), and yttrium (Y).

When the dopant is aluminum (Al), the ferroelectric material film may contain about 3 to about 8 at % (atomic %) of aluminum. In this connection, a content of the dopant may be a content of aluminum based on a sum of hafnium and aluminum.

When the dopant is silicon (Si), the ferroelectric material film may contain about 2 to about 10 a t% of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one of silicon oxide and metal oxide having a high dielectric constant. Although the metal oxide contained in the paraelectric material film may include, for example, at least one of hafnium oxide, zirconium oxide and aluminum oxide. However, the present disclosure is not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the present disclosure is not limited thereto. Because a critical thickness exhibiting the ferroelectric properties may vary based on a type of the ferroelectric material, the thickness of the ferroelectric material film may vary depending on the type of the ferroelectric material.

In one example, the gate insulating film 130 may include one ferroelectric material film. In another example, the gate insulating film 130 may include a plurality of ferroelectric material films spaced apart from one another. The gate insulating film 130 may have a multilayer structure in which a plurality of ferroelectric material films and a plurality of paraelectric material films are alternately stacked on top of one another.

A gate spacer 140 may be disposed on a sidewall (e.g., each of both opposing sidewalls in the first direction DR1) of the gate electrode 120. The gate spacer 140 may extend in the second direction DR2.

For example, the gate spacer 140 may not be disposed between the sheet patterns NS adjacent to one another in the third direction DR3 and between the sheet pattern NS and the lower pattern BP adjacent to one another in the third direction DR3. That is, the gate spacer 140 may include only an outer spacer. In another example, the gate spacer 140 may be further disposed between the sheet patterns NS adjacent to one another in the third direction DR3 and between the sheet pattern NS and the lower patterns BP adjacent to one another in the third direction DR3. That is, the gate spacer 140 may further include an inner spacer.

The gate spacer 140 may include, for example, silicon nitride, silicon oxynitride, silicon oxide, silicon oxycarbonitride, silicon boron nitride, silicon oxyboron nitride, silicon oxycarbide, or a combination thereof.

The source/drain pattern 110 is disposed on the substrate 100. The source/drain pattern 110 may be disposed on the lower pattern BP. The source/drain pattern 110 is in contact with the sheet pattern NS. For example, the source/drain pattern 110 may contact a portion of the gate insulating film 130 disposed between the sheet patterns NS adjacent to one another in the third direction DR3 and between the sheet pattern NS and the lower pattern BP adjacent to one another in the third direction DR3.

The source/drain pattern 110 may be disposed between the gate electrodes 120. The source/drain pattern 110 may be disposed on at least one side of the gate electrode 120. For example, the source/drain pattern 110 may be disposed on each of both opposing sides in the first direction DR1 of the gate electrode 120. Unlike the illustrated example, the source/drain pattern 110 may be disposed on one side of the gate electrode 120 and may not be disposed on the other side of the gate electrode 120.

Unlike the illustrated example, in an example, the source/drain pattern 110 may include a plurality of width extension areas. In the cross-sectional views as shown in FIGS. 2 and 3, an outer sidewall of the source/drain pattern 110 may have a shape of a wavy. In the width extension area, a width in the first direction DR1 of the source/drain pattern 110 may increase and then decrease as the source/drain pattern 110 extends away from the lower pattern BP. The width extension area may be defined between the sheet patterns NS adjacent to one another in the third direction DR3 and between the lowest lower pattern BP and the sheet pattern NS. In the width extension area, a point at which the width of the source/drain pattern 110 is the maximum is located between the lowest sheet pattern NS and the lower pattern BP adjacent to one another in the third direction DR3 or between the sheet pattern NS adjacent to one another in the third direction DR3.

In the cross-sectional views of FIGS. 2 and 3, it is illustrated that a vertical level of an upper surface of the source/drain pattern 110 is higher than a vertical level of an upper surface of the active pattern AP. However, embodiments of the present disclosure are not limited thereto.

The source/drain pattern 110 may include an epitaxial pattern. The source/drain pattern 110 may include, for example, a semiconductor material. The source/drain pattern 110 may contain n-type impurities or p-type impurities. The n-type impurity may include at least one of phosphorus (P), arsenic (As), antimony (Sb), or bismuth (Bi). The p-type impurity may include, for example, at least one of boron (B) or gallium (Ga).

A source/drain etch stop film 145 may be disposed on the upper surface of the field insulating film 105, a sidewall of the gate spacer 140, and a sidewall of the source/drain pattern 110. The source/drain etch stop film 145 may include a material having an etch selectivity with respect to a first interlayer insulating film 150. The source/drain etch stop film 145 may include, for example, silicon nitride, silicon oxynitride, silicon oxycarbonitride, silicon boron nitride, silicon oxycarbide, or a combination thereof. Unlike the illustrated example, the source/drain etch stop film 145 may not be formed.

The first interlayer insulating film 150 may be formed on the field insulating film 105. The first interlayer insulating film 150 may be disposed on the source/drain pattern 110. The first interlayer insulating film 150 may not cover an upper surface of the gate electrode 120.

The first interlayer insulating film 150 may include, for example, at least one of silicon oxide, silicon nitride, silicon oxynitride, or a low dielectric constant material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilyl Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped Silicon Oxide), OSG (SILK), Amorphous Fluorinated Carbon, silica aerogels, silica xerogels, mesoporous silica, or a combination thereof. However, embodiments of the present disclosure are not limited thereto.

The source/drain contact 160 may be disposed on the active pattern AP. The source/drain contact 160 may be disposed on the source/drain pattern 110. The source/drain contact 160 is electrically connected to the source/drain pattern 110.

The source/drain contact 160 may be disposed between the gate electrodes 120 adjacent to one another in the first direction DR1. For example, the source/drain contact 160 may extend in the second direction DR2 while being disposed between the gate electrodes 120 neighboring to one another in the first direction DR1. The source/drain contact 160 may extend in the second direction DR2 so as to be electrically connected to the source/drain patterns 110 respectively disposed on different active patterns AP. In another example, unlike the illustrated example, the source/drain patterns 110 respectively disposed on different active patterns AP may be electrically connected to different source/drain contacts 160, respectively.

The source/drain contact 160 may be disposed in the first interlayer insulating film 150. The source/drain contact 160 may extend through the source/drain etch stop film 145. A vertical level of the lowermost surface of the source/drain contact 160 is lower than a vertical level of the upper surface of the source/drain pattern 110.

A contact silicide film 165 may be disposed between the source/drain contact 160 and the source/drain pattern 110. The contact silicide film 165 is disposed on the source/drain pattern 110. The contact silicide film 165 may include, for example, a metal silicide material.

The source/drain contact 160 may include a first portion 161 and a second portion 162. The first portion 161 may be disposed on the source/drain pattern 110. The first portion 161 may be disposed on the contact silicide film 165. The first portion 161 may be in contact with the contact silicide film 165. The second portion 162 may be disposed on the first portion 161.

The first portion 161 may extend in the second direction DR2. The second portion 162 may protrude from the first portion 161 in the third direction DR3. A width in the second direction DR2 of the first portion 161 may be greater than a width in the second direction DR2 of the second portion 162. A width in the first direction DR1 of the first portion 161 may be equal to a width in the first direction DR1 of the second portion 162. For example, an upper surface of the first portion 161 may be coplanar with an upper surface of the first interlayer insulating film 150. For example, the second portion 162 may overlap the active pattern AP in the third direction DR3. However, embodiments of the present disclosure are not limited thereto. For example, the second portion 162 may overlap the field insulating film 105 in the third direction DR3.

The source/drain contact 160 may include a conductive material. The source/drain contact 160 may include, for example, at least one of a metal, a metal alloy, a conductive metal nitride, a conductive metal carbide, a conductive metal oxide, a conductive metal carbonitride, and a two-dimensional (2D) material. Although the source/drain contact 160 is illustrated as being a single film, it is intended only for convenience of illustration and embodiments of the present disclosure are not limited thereto. Unlike the illustrated example, the source/drain contact 160 may have a multi-conductive film structure. The source/drain contact 160 may include, for example, a barrier film and a filling film on the barrier film.

A conductive film 167 may be disposed on the second portion 162 of the source/drain contact 160. The conductive film 167 may be disposed on the second portion 122 of the gate electrode 120. The conductive film 167 may be in contact with the second portion 162 of the source/drain contact 160. The conductive film 167 may be disposed with the second portion 122 of the gate electrode 120.

The conductive film 167 may include at least one of a metal, a metal alloy, a conductive metal nitride, a metal silicide, a doped semiconductor material, a conductive metal oxide, and a conductive metal oxynitride. The conductive film 167 may include, for example, titanium nitride.

The isolation insulating film 170 may be disposed on the first interlayer insulating film 150, the gate electrode 120, and the source/drain contact 160. The isolation insulating film 170 may be in contact with an upper surface of the first interlayer insulating film 150. A vertical level of a bottom surface of the isolation insulating film 170 may be lower than a vertical level of the uppermost surface of the source/drain contact 160. The vertical level of the bottom surface of the isolation insulating film 170 may be lower than a vertical level of the uppermost surface of the gate electrode 120. A vertical level of the upper surface of the isolation insulating film 170 may be higher than a vertical level of the uppermost surface of the source/drain contact 160. A vertical level of the uppermost surface of the isolation insulating film 170 may be higher than a vertical level of the uppermost surface of the gate electrode 120.

The isolation insulating film 170 may include a first film 171 and a second film 172. The second film 172 may be disposed on the first film 171. A sidewall of the second film 172 may include a lower portion 172S1 and an upper portion 172S2. The first film 171 may extend along a bottom surface of the second film 172 and a lower portion 172S1 of a sidewall of the second film 172 and may not extend along an upper portion 172S2 of the sidewall of the second film 172. The upper portion 172S2 of each of both opposing sidewalls in the first direction DR1 of the second film 172 and the upper portion 172S2 of each of both opposing sidewalls in the second direction DR2 of the second film 172 may not be covered with the first film 171 so as to be exposed. Each of both opposing sidewalls in the first direction DR1 of the isolation insulating film 170 and each of both opposing sidewalls in the second direction DR2 thereof may have a step. The bottom surface of the isolation insulating film 170 may be a bottom surface of the first film 171, and the uppermost surface of the isolation insulating film 170 may be an upper surface of the second film 172.

The first portion 161 of the source/drain contact 160 may not overlap the isolation insulating film 170 in each of the first direction DR1 and the second direction DR2, and the second portion 162 of the source/drain contact 160 may overlap the isolation insulating film 170 in each of the first direction DR1 and the second direction DR2.

Each of both opposing sidewalls in the first direction DR1 of the first portion 161 of the source/drain contact 160 may be in contact with the source/drain etch stop film 145. Each of both opposing sidewalls in the second direction DR2 of the first portion 161 of the source/drain contact 160 may be in contact with the first interlayer insulating film 150.

In some embodiments, at least one of both opposing sidewalls in the first direction DR1 of the second portion 162 of the source/drain contact 160 may be in contact with the isolation insulating film 170. At least one of both opposing sidewalls in the first direction DR1 of the second portion 162 of the source/drain contact 160 may be in contact with the first film 171. For example, both opposing sidewalls in the first direction DR1 of the second portion 162 of the source/drain contact 160 may be in contact with the first film 171. In other words, the isolation insulating film 170 may be partially intruded into the source/drain contact 160, and a sidewall and a bottom surface of a portion of the isolation insulating film 170 extending into the source/drain contact 160 may be in contact with the source/drain contact 160.

Each of both opposing sidewalls in the second direction DR2 of the second portion 162 of the source/drain contact 160 may be in contact with the isolation insulating film 170. Each of both opposing sidewalls in the second direction DR2 of the second portion 162 of the source/drain contact 160 may be in contact with the first film 171. A portion of the upper surface of the first portion 161 on which the second portion 162 of the source/drain contact 160 is not disposed may be in contact with the isolation insulating film 170. A portion of the upper surface of the first portion 161 on which the second portion 162 of the source/drain contact 160 is not disposed may be in contact with the first film 171.

The first portion 121 of the gate electrode 120 may not overlap the isolation insulating film 170 in each of the first direction DR 1 and the second direction DR2, and the second portion 122 of the gate electrode 120 may overlap the isolation insulating film 170 in each of the first direction DR1 and the second direction DR2.

In some embodiments, at least one of both opposing sidewalls in the first direction DR1 of the second portion 122 of the gate electrode 120 may be in contact with the insulation insulating film 170. At least one of both opposing sidewalls in the first direction DR1 of the second portion 122 of the gate electrode 120 may be in contact with the first film 171. For example, both opposing sidewalls in the first direction DR1 of the second portion 122 of the gate electrode 120 may be in contact with the first film 171. In other words, the isolation insulating film 170 may be partially intruded into the uppermost portion of the gate electrode 120, such that a sidewall and a bottom surface of the portion of the isolation insulating film 170 extending into the gate electrode 120 may be in contact with the gate electrode 120.

Each of both opposing sidewalls in the second direction DR2 of the second portion 122 of the gate electrode 120 may be in contact with the isolation insulating film 170. Each of both opposing sidewalls in the second direction DR2 of the second portion 122 of the gate electrode 120 may be in contact with the first film 171. A portion of an upper surface of the first portion 121 on which the second portion 122 of the gate electrode 120 is not disposed may be in contact with the isolation insulating film 170. A portion of an upper surface of the first portion 121 on which the second portion 122 of the gate electrode 120 is not disposed may be in contact with the first film 171.

The first film 171 and the second film 172 may include different insulating materials. In some embodiments, the first film 171 may include silicon oxycarbide and the second film 172 may be silicon nitride. For example, the first film 171 may be made of a conformal SiOC low temperature (COLT). In some embodiments, the first film 171 may include silicon and the second film 172 may be silicon oxide.

The isolation insulating film 170 may not cover at least a portion of the at least one gate electrode 120 and at least a portion of the at least one source/drain contact 160. The isolation insulating film 170 may not cover the second portion 122 of the gate electrode 120 and the second portion 162 of the source/drain contact 160. For example, a first via trench 180T and a second via trench 190T may be formed in the isolation insulating film 170.

The first via trench 180T may expose at least a portion of the source/drain contact 160. A sidewall of the first via trench 180T may be defined by the isolation insulating film 170. The sidewall of the first via trench 180T may be defined by the second film 172. The sidewall of the first via trench 180T may be defined by the upper portion 172S2 of the sidewall of the second film 172. A bottom surface of the first via trench 180T may be defined by the conductive film 167 on the second portion 162 of the source/drain contact 160 and the uppermost surface of the first film 171. For example, the upper surface of the conductive film 167 may be substantially coplanar with the uppermost surface of the first film 171.

The second via trench 190T may expose at least a portion of the gate electrode 120. A sidewall of the second via trench 190T may be defined by the isolation insulating film 170. The sidewall of the second via trench 190T may be defined by the second film 172. The sidewall of the second via trench 190T may be defined by the upper portion 172ST of the second film 172. A bottom surface of the second via trench 190T may be defined by the conductive film 167 on the second portion 122 of the gate electrode 120 and the uppermost surface of the first film 171.

The source/drain via 180 may be disposed on the source/drain contact 160. The source/drain via 180 may be disposed on the second portion 162 of the source/drain contact 160. The source/drain via 180 may be disposed on the conductive film 167. The conductive film 167 may be disposed between the second portion 162 of the source/drain contact 160 and the source/drain via 180. A bottom surface of the source/drain via 180 may be in contact with the conductive film 167 and the first film 171. The source/drain via 180 is electrically connected to the source/drain contact 160. The source/drain via 180 may fill the first via trench 180T. A sidewall of the source/drain via 180 may be in contact with the upper portion 172S2 of a sidewall of the second film 172.

The gate via 190 may be disposed on the gate electrode 120. The gate via 190 may be disposed on the second portion 122 of the gate electrode 120. The gate via 190 may be disposed on the conductive film 167. The conductive film 167 may be disposed between the second portion 122 of the gate electrode 120 and the gate via 190. A bottom surface of the gate via 190 may be in contact with the conductive film 167 and the first film 171. The gate via 190 is electrically connected to the gate electrode 120. The gate via 190 may fill the second via trench 190T. The gate via 190 may be in contact with the upper portion 172S2 of a sidewall of the second film 172.

In an area which the source/drain via 180 is not disposed, the source/drain contact 160 may include only the first portion 161. In an area in which the gate via 190 is not disposed, the gate electrode 120 may include only the first portion 121.

The source/drain via 180 and the gate via 190 may further extend along and on an upper surface of the second film 172. For example, the source/drain via 180 may include a first portion 181 and a second portion 182 on the first portion 181, and the gate via 190 may include a first portion 191 and a second portion 192 on the first portion 191.

The first portion 181 may fill the first via trench 180T. The second portion 182 may be connected to the first portion 181 and may extend along and on an upper surface of the second film 172. For example, in at least one of the first direction DR1 and the second direction DR2, a width of the second portion 182 may be greater than a width of the first portion 181. The first portion 191 may fill the second via trench 190T. The second portion 192 may be connected to the first portion 191 and may extend along and on an upper surface of the second film 172. For example, in at least one of the first direction DR1 and the second direction DR2, a width of the second portion 192 may be greater than a width of the first portion 191.

A second interlayer insulating film 195 may be disposed on the insulation insulating film 170. A sidewall of the first portion 181 may be in contact with the second film 172, and a sidewall of the second portion 182 may be in contact with the second interlayer insulating film 195. A sidewall of the first portion 191 may be in contact with the second film 172, and a sidewall of the second portion 192 may be in contact with the second interlayer insulating film 195. The second interlayer insulating film 195 may include, for example, at least one of silicon oxide, silicon nitride, silicon oxynitride, or a low dielectric constant material.

A via and a wiring on the via may be further disposed on the second portion 182 of the source/drain via 180. The via and the wiring on the via may be further disposed on the second portion 192 of the gate via 190.

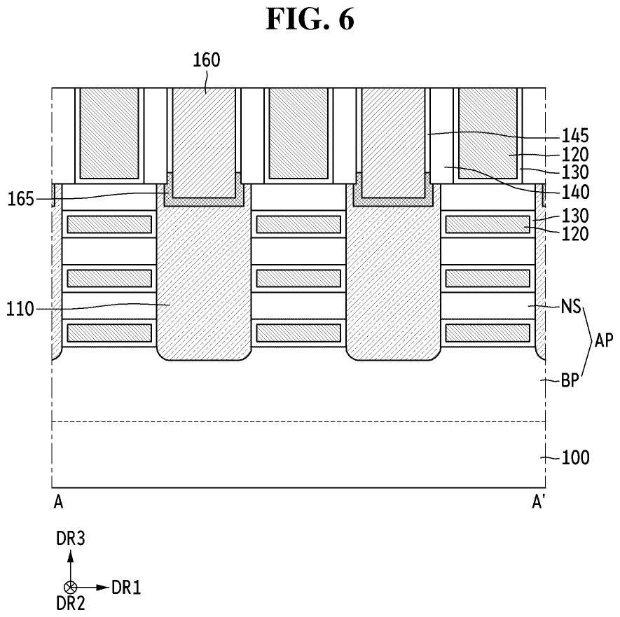

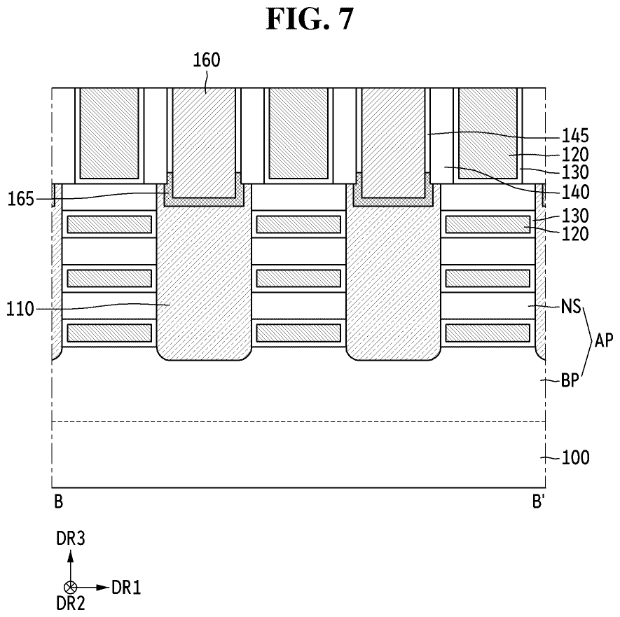

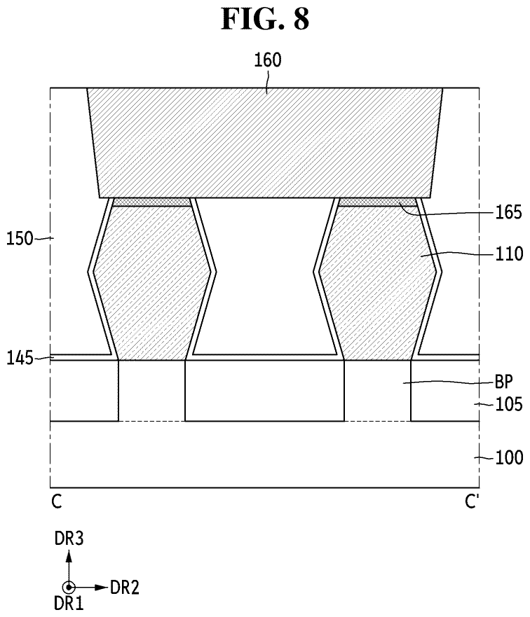

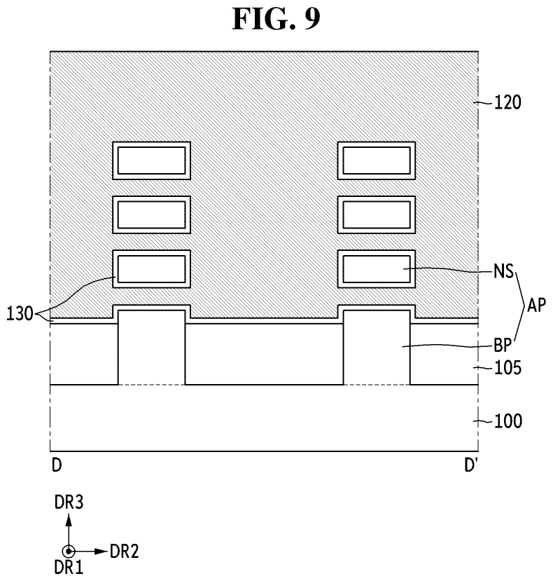

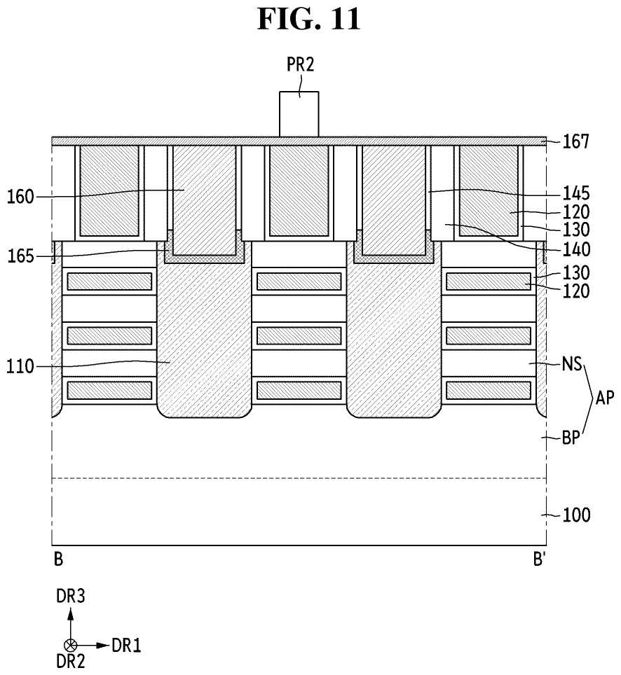

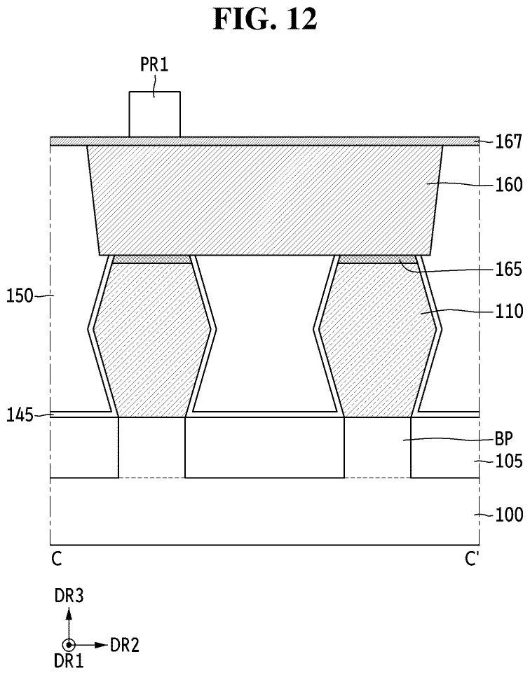

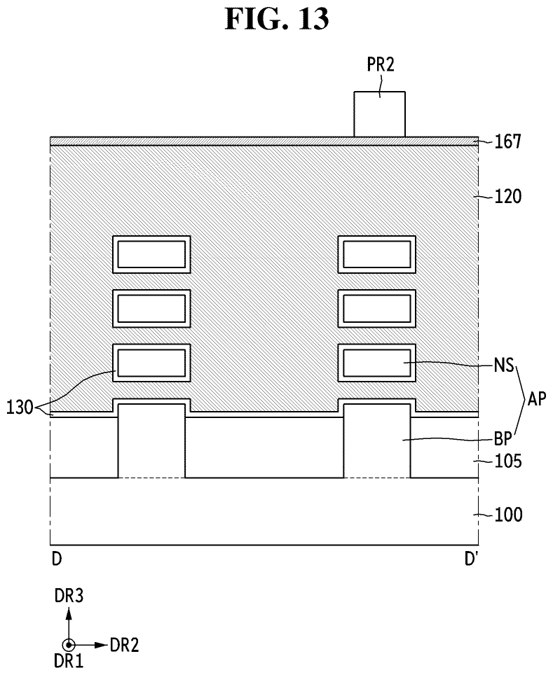

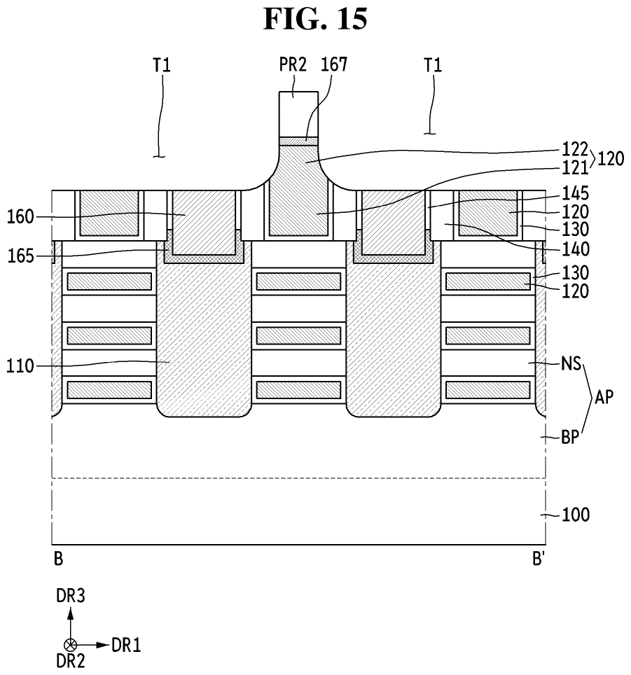

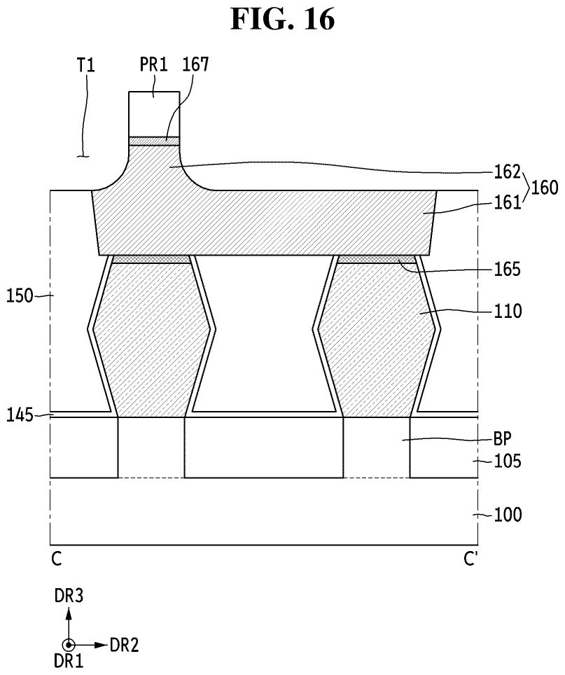

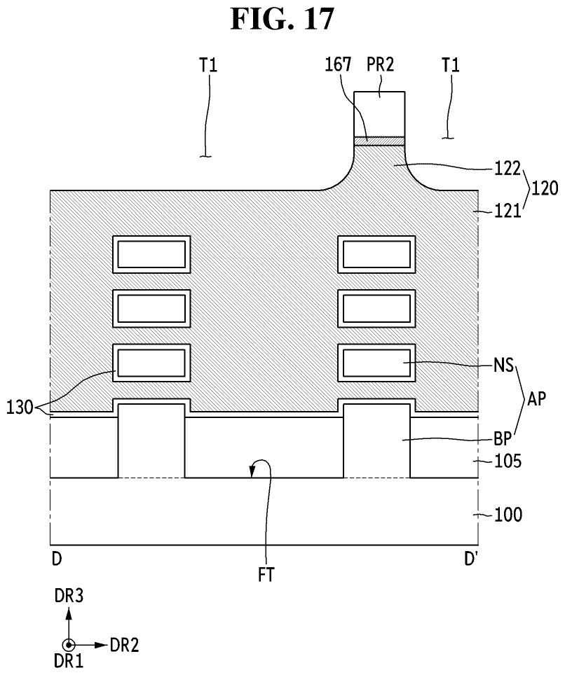

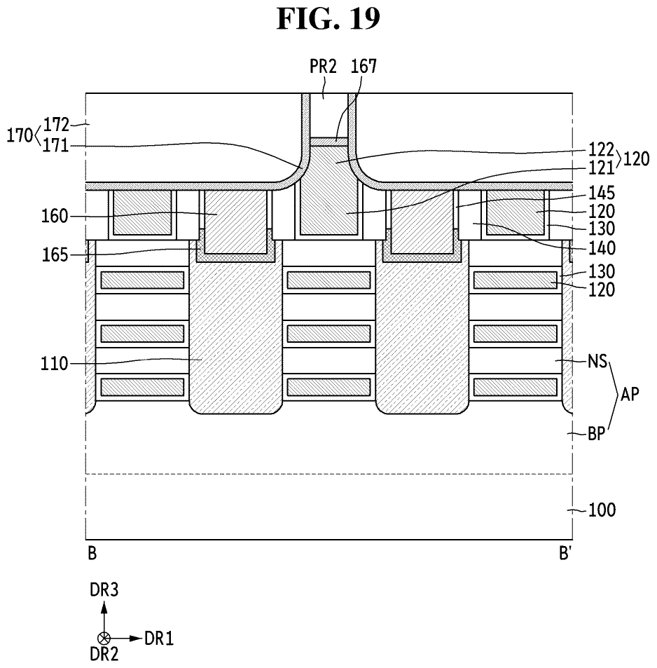

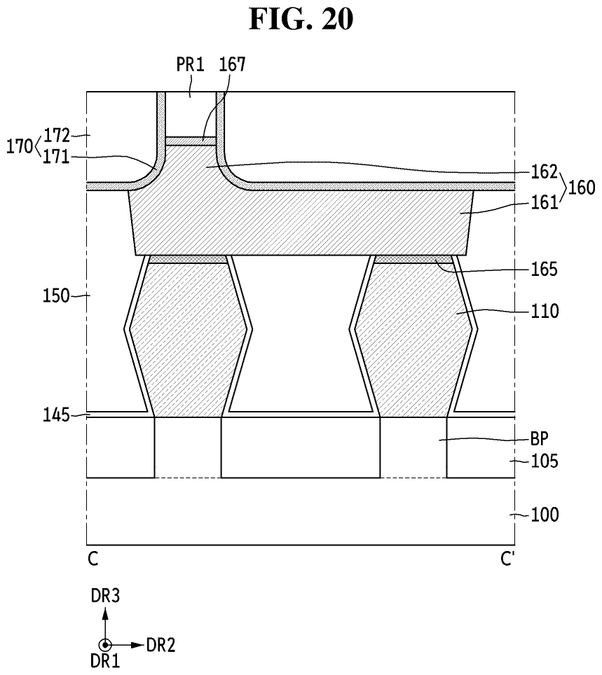

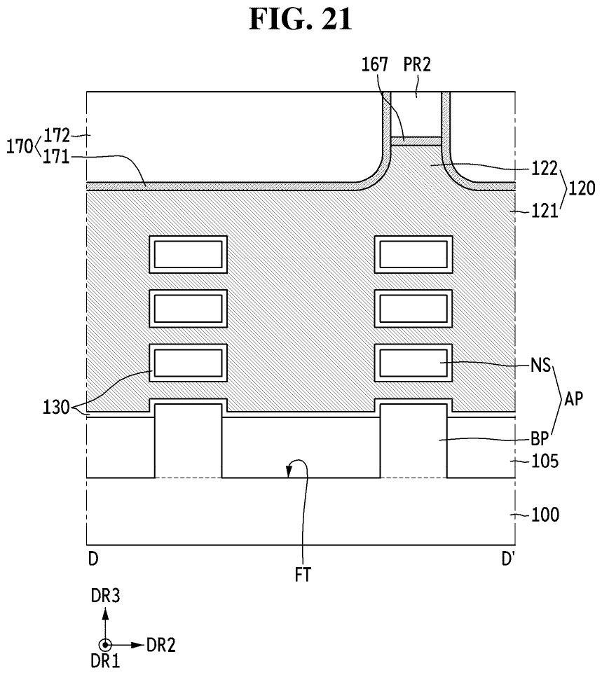

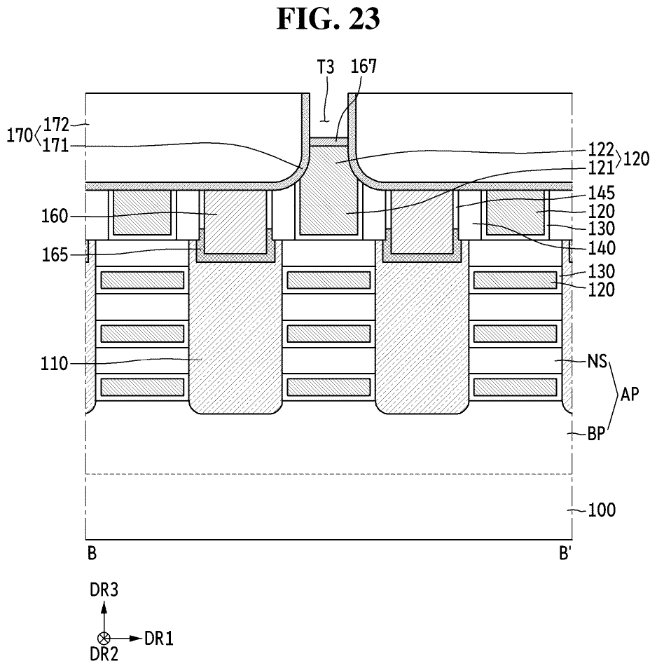

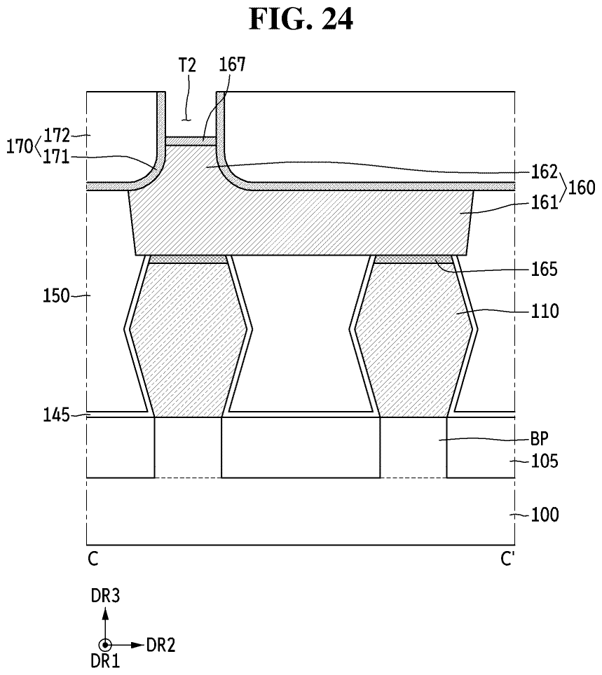

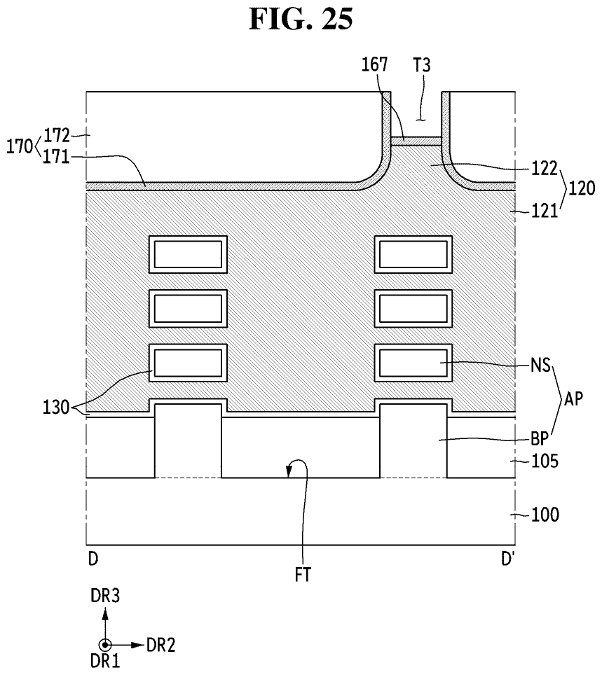

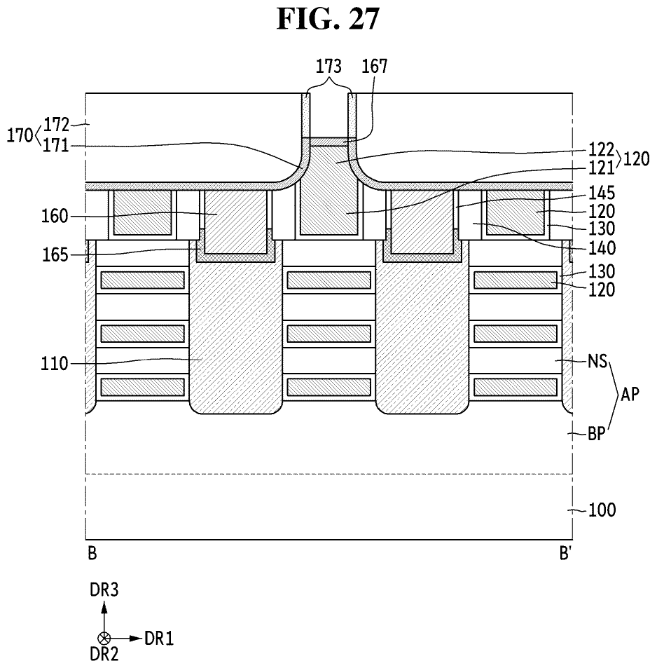

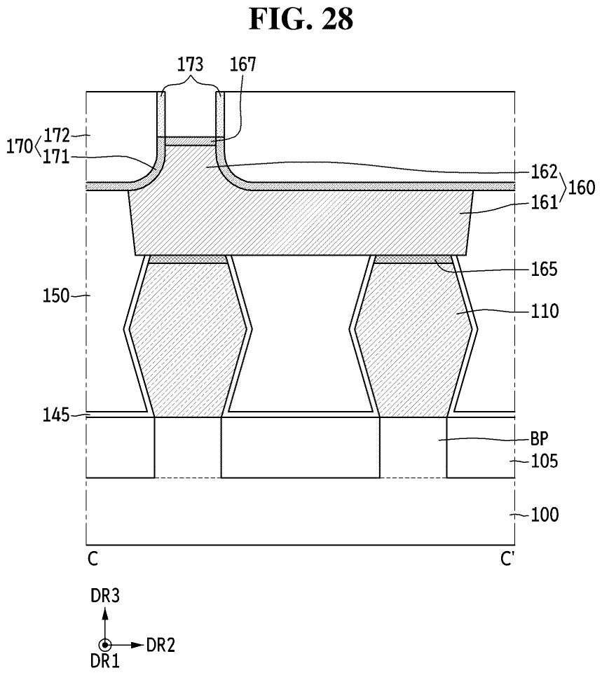

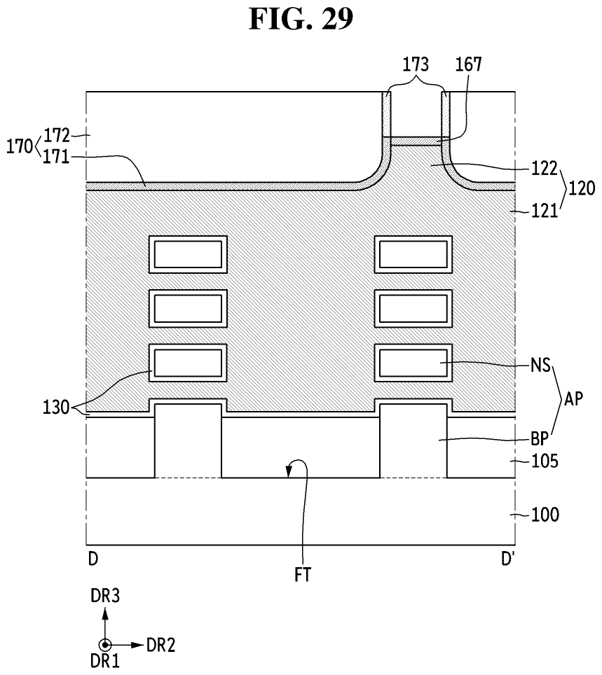

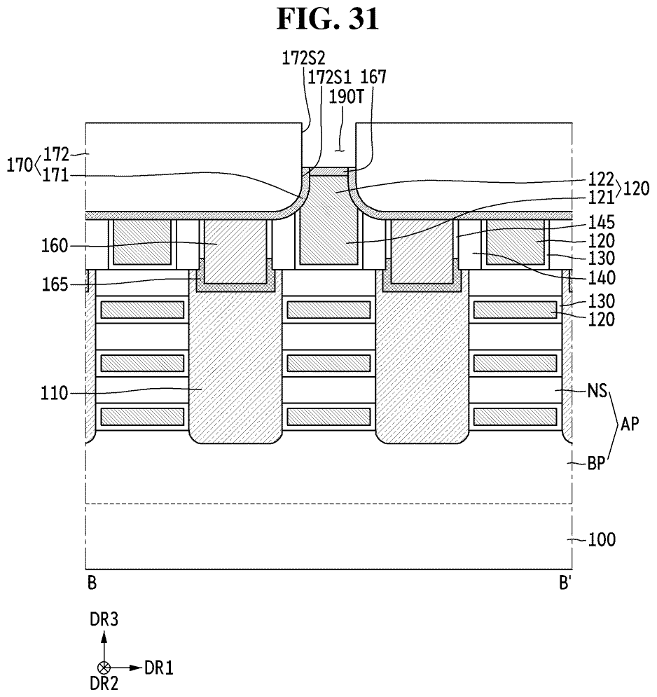

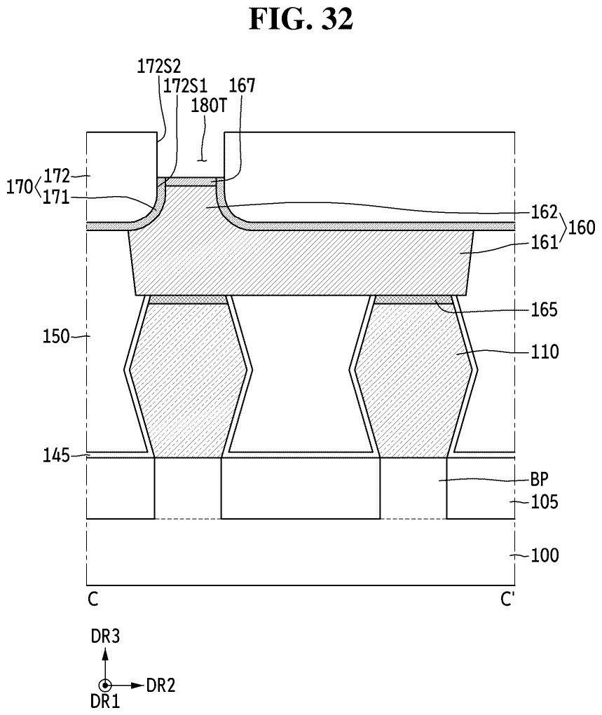

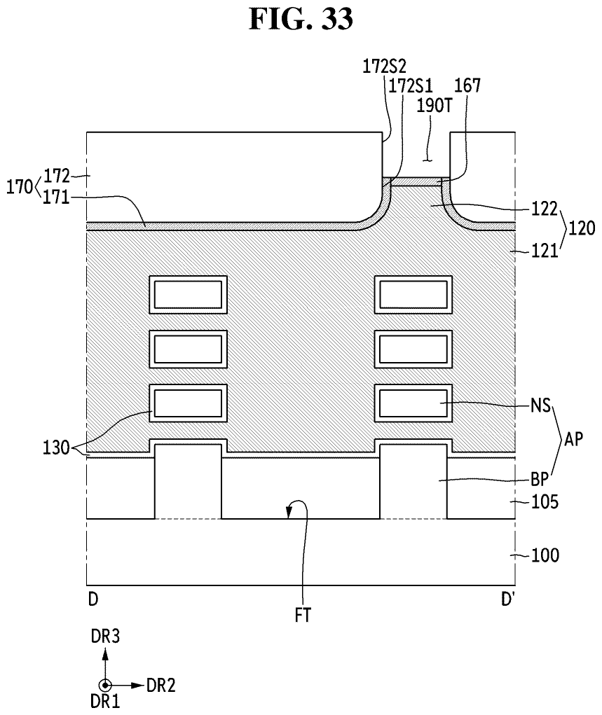

FIGS. 6 to 33 are diagrams of intermediate structures corresponding to intermediate steps of a method for manufacturing a semiconductor device according to some embodiments.

Referring to FIGS. 6 to 9, the source/drain pattern 110 may be formed on the active pattern AP. The source/drain etch stop film 145 and the first interlayer insulating film 150 may be sequentially formed on the source/drain pattern 110.

Subsequently, the gate insulating film 130 and the gate electrode 120 may be formed in a RMG (Replacement Metal Gate) process. The gate insulating film 130 may be formed along and on an upper surface of the field insulating film 105 and an upper surface of the lower pattern BP. The gate insulating film 130 may be formed along and on the circumference of the sheet pattern NS. The gate electrode 120 may be formed on the gate insulating film 130. The gate spacer 140 may be formed on a sidewall of the gate electrode 120. The gate electrode 120 may be formed between adjacent source/drain patterns 110.

Subsequently, the source/drain contact 160 may be formed on the source/drain pattern 110. The source/drain contact 160 may be formed in the first interlayer insulating film 150. Each of both opposing sidewalls in the first direction DR1 of the source/drain contact 160 may contact the source/drain etch stop film 145. Each of both opposing sidewalls in the second direction DR2 of the source/drain etch stop film 145 may be in contact with the first interlayer insulating film 150. An upper surface of a preliminary gate electrode 120P, an upper surface of the gate insulating film 130, an upper surface of the gate spacer 140, and an upper surface of the first interlayer insulating film 150 may be coplanar with one another.

While the source/drain contact 160 is formed, the contact silicide film 165 may be formed along an interface between the source/drain contact 160 and the source/drain pattern 110.

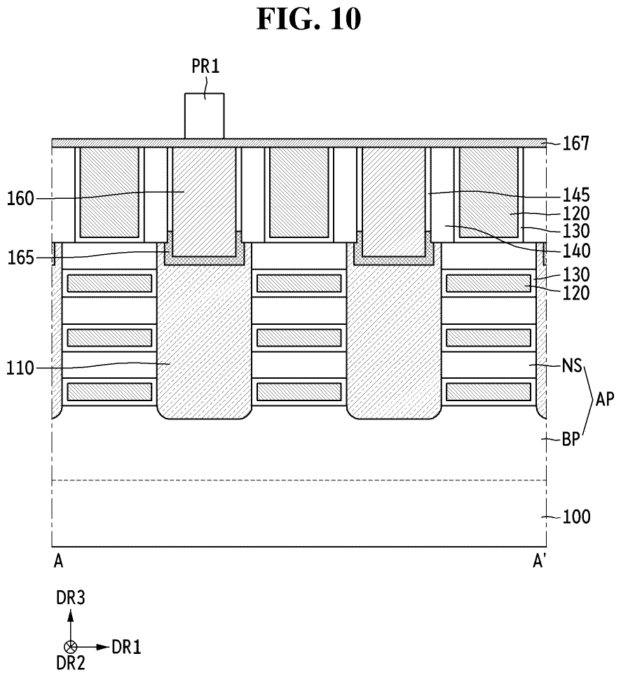

Referring to FIGS. 10 to 14, the conductive film 167 may be formed on an upper surface of the gate electrode 120, an upper surface of the gate insulating film 130, an upper surface of the gate spacer 140, and an upper surface of the first interlayer insulating film 150.

First and second photoresist patterns PR1 and PR2 may be formed on the conductive film 167. The first photoresist pattern PR1 may be formed on the source/drain contact 160. The second photoresist pattern PR2 may be formed on the gate electrode 120. The first photoresist pattern PR1 may be formed at a position where the source/drain via 180 is formed later. The second photoresist pattern PR 2 may be formed at a position where the gate via 190 is formed later.

For example, each of the first and second photoresist patterns PR1 and PR2 may include oxide.

In the first direction DR1, the width of the first photoresist pattern PR1 may be smaller than or equal to the width of the preliminary source/drain contact 160P In the first direction DR1, the width of the second photoresist pattern PR2 may be smaller than or equal to the width of the preliminary gate electrode 120P.

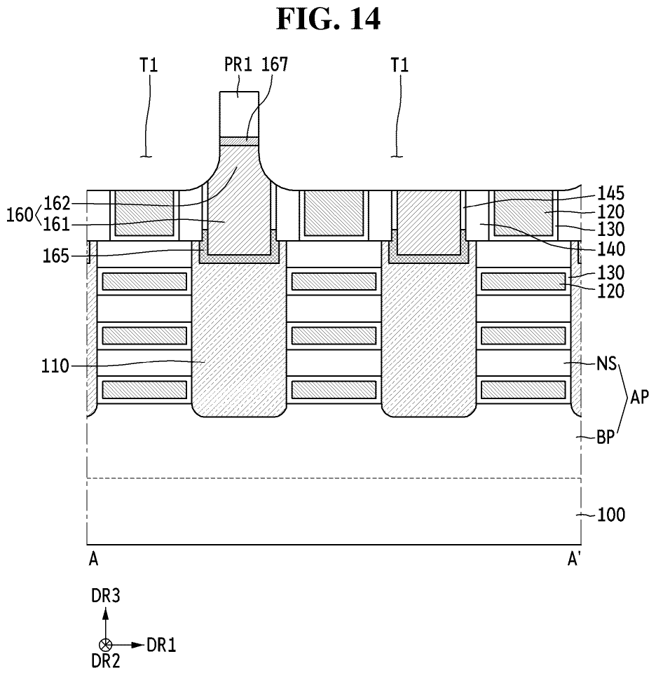

Referring to FIGS. 14 to 17, a first trench T1 may be formed using the first and second photoresist patterns PR1 and PR2. A portion of the source/drain contact 160, a portion of the source/drain etch stop film 145, a portion of the first interlayer insulating film 150, a portion of the gate electrode 120, a portion of the gate insulating film 130, and a portion of the gate spacer 140 may be etched to form the first trench T1. Accordingly, the source/drain contact 160 may include the first portion 161 and the second portion 162 protruding from the first portion 161 in the third direction DR3, and the gate electrode 120 may include the first portion 121 and the second portion 122 protruding from the first portion 121 in the third direction DR3. A sidewall of the second portion 162 of the source/drain contact 160 and an upper surface of the first portion 161 of the source/drain contact 160 may be defined by the first trench T1. A sidewall of the second portion 122 of the gate electrode 120 and an upper surface of the first portion 121 of the gate electrode 120 may be defined by the first trench T1. The first trench T1 may expose the gate electrode 120 and the source/drain contact 160.

For example, each of the first film 171 and the second film 172 may include a material having an etch selectivity with respect to the first and second photoresist patterns PR1 and PR2.

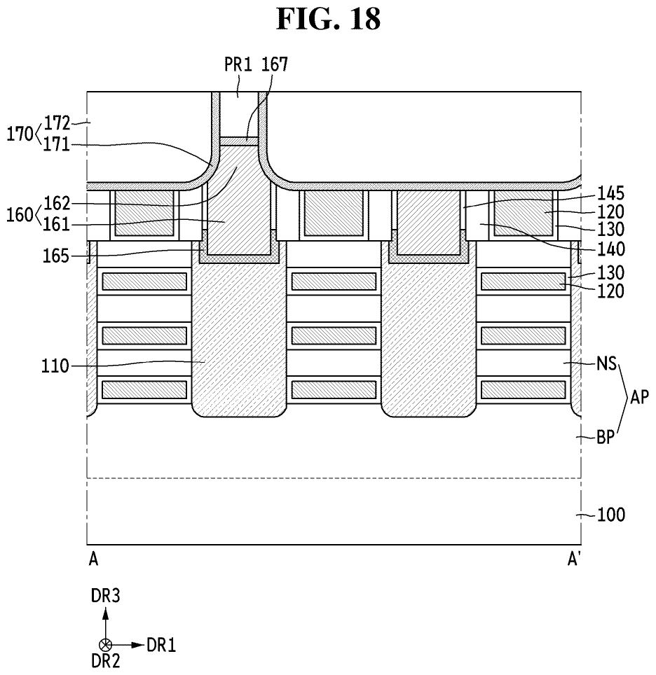

Referring to FIGS. 18 to 21, the isolation insulating film 170 may be formed to fill the first trench T1. The isolation insulating film 170 may include the first film 171 and the second film 172. The first film 171 may be formed along and on the first trench T1. The first film 171 may be conformally formed along and on the first trench T1. The second film 172 may fill the first trench T1 while being disposed on the first film 171.

For example, the first film 171 extending along an upper surface of each of the first trench T1 and the first and second photoresist patterns PR1 and PR2 and the second film 172 disposed on the first film 171 may be formed. Subsequently, a planarization process may be performed until upper surfaces of the first and second photoresist patterns PR1 and PR2 are exposed to form the isolation insulating film 170. The upper surface of the isolation insulating film 170 and the upper surfaces of the first and second photoresist patterns PR1 and PR2 may be substantially coplanar with one another.

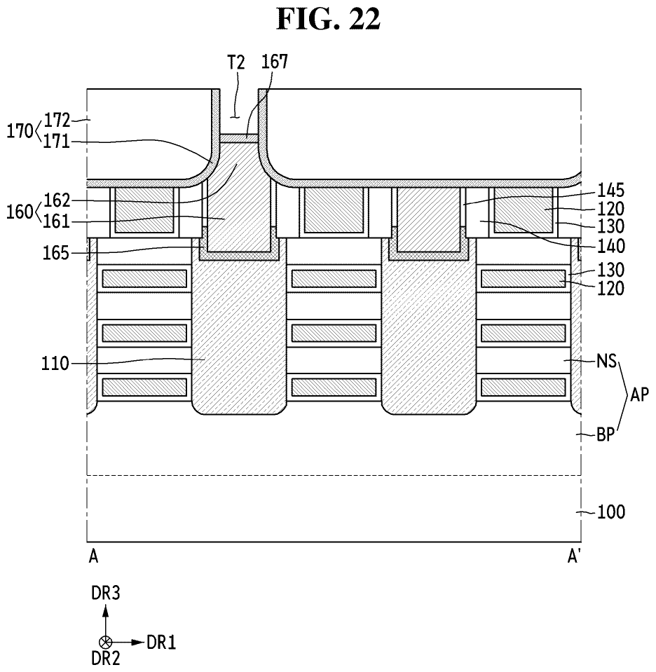

Referring to FIGS. 22 to 26, the first and second photoresist patterns PR1 and PR2 of FIGS. 18 to 21 may be removed to form a second trench T2. The second trench T2 may expose the conductive film 167 and the first film 171.

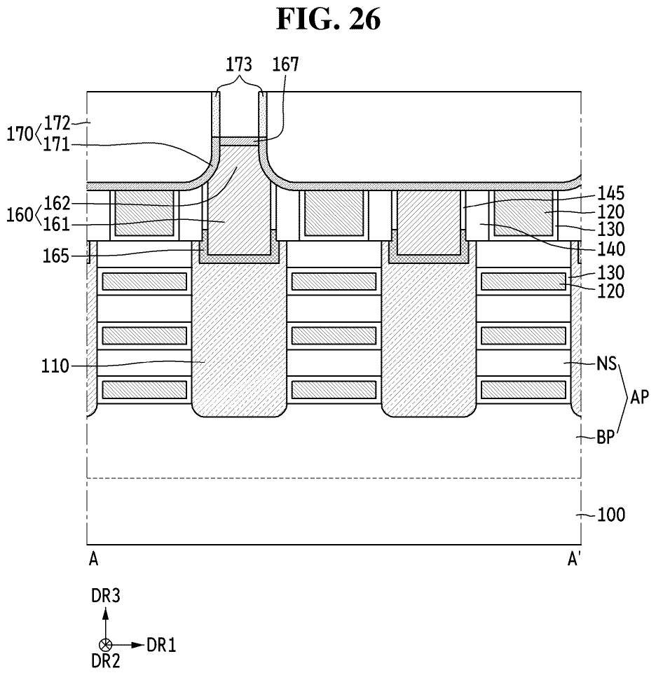

Referring to FIGS. 26 to 29, plasma treatment may be performed on a portion of the first film 171 exposed through the second trench T2 to form a third film 173. The third film 173 may include a material different from that of each of the first film 171 and the second film 172.

In some embodiments, the first film 171 may include silicon oxycarbide, the second film 172 may include silicon nitride, and the oxygen plasma treatment may be performed on a portion of the first film 171 exposed through the second trench T2 to form the third film 173 including silicon oxide. A portion of the first film 171 exposed through the second trench T2 and subjected to the oxygen plasma treatment may become the third film 173.

In some embodiments, the first film 171 may include silicon and the second film 172 may include silicon oxide, and a nitrogen plasma treatment may be performed on the portion of the first film 171 exposed through the second trench T2 to form the third film 173 including silicon oxynitride. The portion of the first film 171 exposed through the second trench T2 and subjected to the nitrogen plasma treatment may become the third film 173.

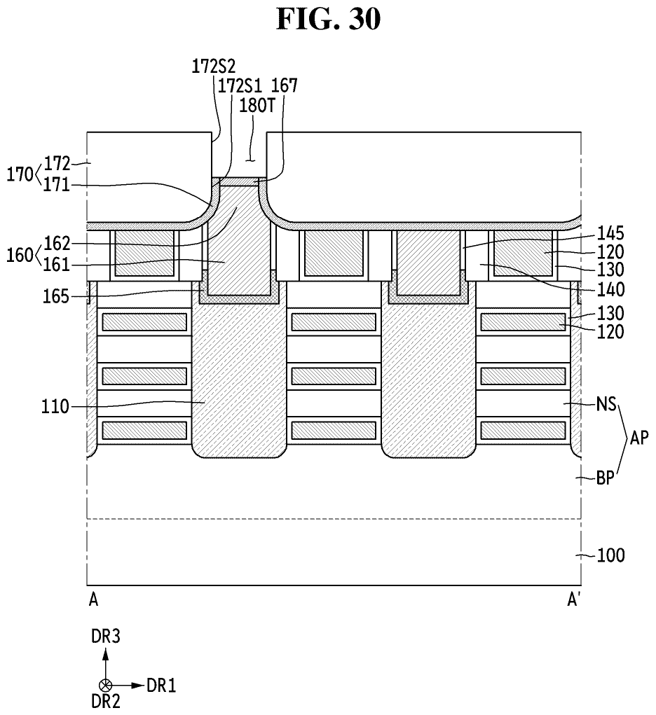

Referring to FIGS. 30 to 33, the third layer (173 of FIGS. 26 to 29) may be removed to form the first via trench 180T and the second via trench 190T. The first via trench 180T and the second via trench 190T may expose the upper portion 172S2 of the sidewall of the second film 172. Accordingly, the sidewall of the isolation insulating film 170 may have the step.

For example, when the third film (173 of FIGS. 26 to 29) includes silicon oxide, the third film (173 of FIGS. 26 to 29) may be removed by an etching process using a HF solution.

Referring to FIGS. 2 to 6, the source/drain via 180, the gate via 190, and the second interlayer insulating film 195 may be formed. The source/drain via 180 may fill the first via trench 180T, and the gate via 190 may fill the second via trench 190T. The second interlayer insulating film 195 may surround a sidewall of a portion of the source/drain via 180 on top of the isolation insulating film 170 and a sidewall of the gate via 190 on top of the isolation insulating film 170.

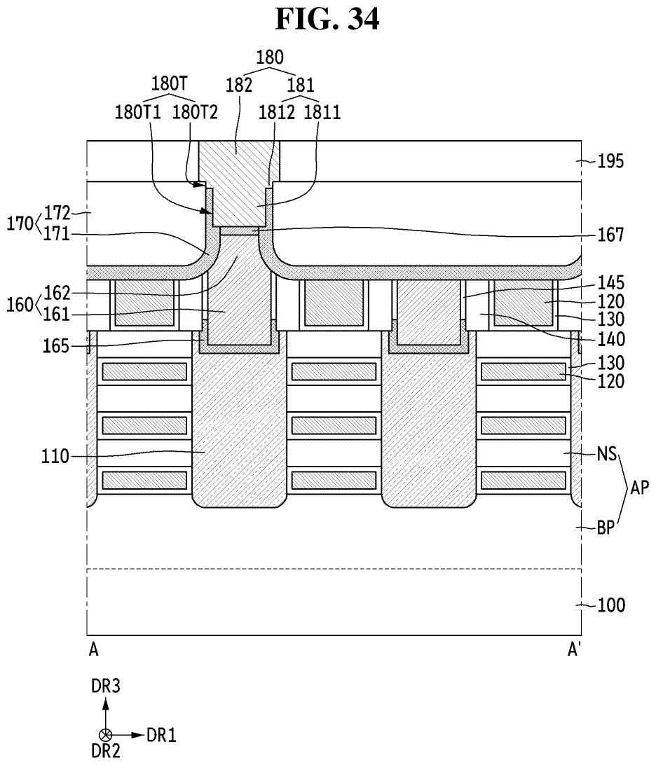

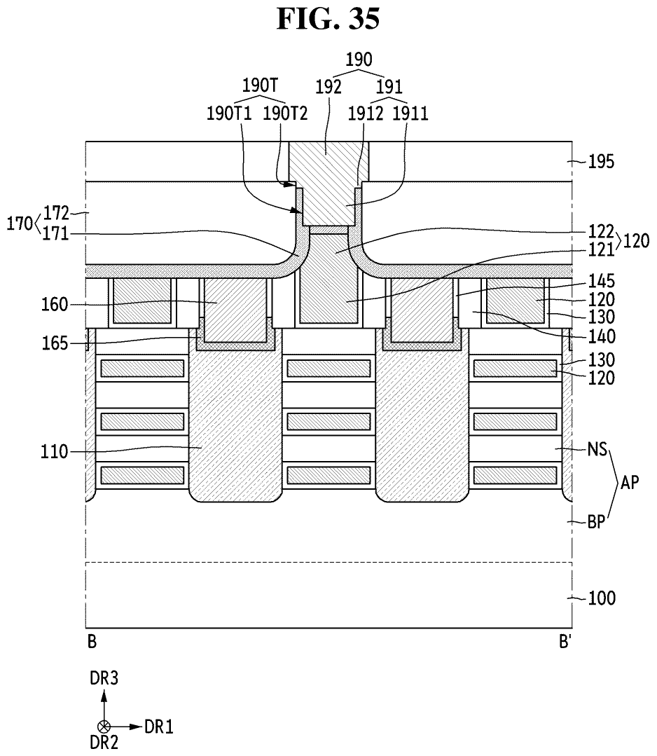

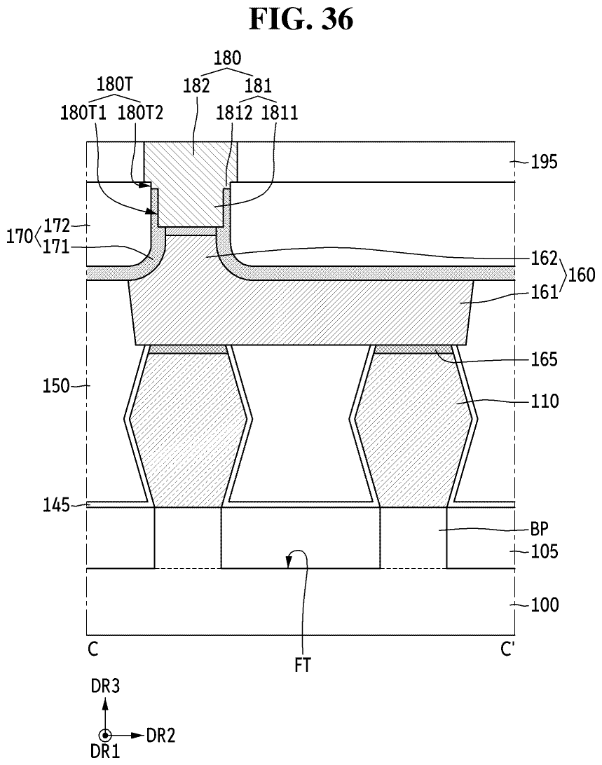

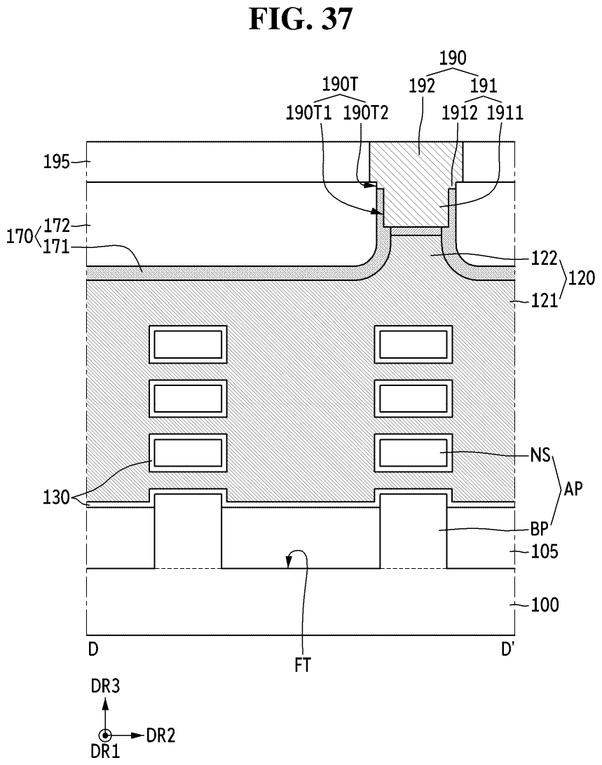

FIGS. 34 to 37 are diagrams for illustrating a semiconductor device according to some embodiments. For convenience of description, differences thereof from those as described above with reference to FIGS. 1 to 5 will be mainly described.

Referring to FIGS. 34 to 37, in the semiconductor device according to some embodiments, the first via trench 180T may include a first lower trench 180T1 and a first upper trench 180T2. The first upper trench 180T2 may be connected to the first lower trench 180T1 and may be formed on the first lower trench 180T1. A width in each of the first direction DR1 and the second direction DR2 of the first lower trench 180T1 may be smaller than a width in each of the first direction DR1 and the second direction DR2 of the first upper trench 180T2.

The sidewall of the first lower trench 180T1 may be defined by the first film 171. The bottom surface of the first lower trench 180T1 may be defined by the first film 171 and the conductive film 167. The sidewall of the first upper trench 180T2 may be formed by the second film 172. The sidewall of the first upper trench 180T2 may be defined by the upper portion 172S2 of the sidewall of the second film 172. The bottom surface of the first upper trench 180T2 may be defined by the upper surface of the first film 171.

The first portion 181 of the source/drain via 180 may include a first lower portion 1811 and a first upper portion 1812. The first lower portion 1811 may fill the first lower trench 180T1, and the first upper portion 1812 may fill the first upper trench 180T2. A width in each of the first direction DR1 and the second direction DR2 of the first lower portion 1811 may be smaller than a width in each of the first direction DR1 and the second direction DR2 of the first upper portion 1812. The sidewall of the first lower portion 1811 may be in contact with the first film 171. The sidewall of the first upper portion 1812 may be in contact with the second film 172. The sidewall of the source/drain via 180 may be in contact with the first film 171 and the second film 172.

The second via trench 190T may include a second lower trench 190T1 and a second upper trench 190T2. The second upper trench 190T2 may be connected to the second lower trench 190T1 and may be formed on the second lower trench 190T1. A width in each of the first direction DR1 and the second direction DR2 of the second lower trench 190T1 may be smaller than a width in each of the first direction DR1 and the second direction DR2 of the second upper trench 190T2.

The sidewall of the second lower trench 190T1 may be defined by the first film 171. The bottom surface of the second lower trench 190T1 may be defined by the first film 171 and the conductive film 167. A sidewall of the second upper trench 190T2 may be defined by the second film 172. The sidewall of the second upper trench 190T2 may be defined by the upper portion 172S2 of a sidewall of the second film 172. The bottom surface of the second upper trench 190T2 may be defined by the upper surface of the first film 171.

The first portion 191 of the gate via 190 may include a second lower portion 1911 and a second upper portion 1912. The second lower portion 1911 may fill the second lower trench 180T1, and the second upper portion 1912 may fill the second upper trench 180T2. A width in each of the first direction DR1 and the second direction DR2 of the second lower portion 1911 may be smaller than a width in each of the first direction DR1 and the second direction DR2 of the second upper portion 1912. The sidewall of the second lower portion 1911 may be in contact with the first film 171. The sidewall of the second upper portion 1912 may be in contact with the second film 172. A sidewall of the gate via 190 may be in contact with the first film 171 and the second film 172.

Referring to FIGS. 6 to 33, when the first trench T1 is formed using the photoresist patterns PR1 and PR2, a corner (a portion connecting a bottom surface and a sidewall of the first trench T1 to one another) of the first trench T1 may have a round shape. When a width of (for example, a width in the first direction DR1) each of the photoresist patterns PR1 and PR2 is large, a roundness of each of the corner of the first trench T1 may be large. As the roundness of the corner of the first trench T1 increases, a vertical level of each of the uppermost surface of the gate electrode 120 in contact with the first trench T1 and the uppermost surface of the source/drain contact 160 in contact with the first trench T1 may be higher. As the roundness of the corner of the first trench T1 increases, each of a distance between the source/drain via 180 and the gate electrode 120 adjacent to one another and a distance between the gate via 190 and the source/drain contact 160 adjacent to one another may decrease.

On the other hand, in the method for manufacturing the semiconductor device according to some embodiments, the first trench T1 is formed using the photoresist patterns PR1 and PR2 having a smaller width, the third film 173 is formed by performing plasma treatment, and the first via trench 180T and the second via trench 190T are formed by removing the third film 173. The roundness of the corner of the first trench T1 may be reduced using the photoresist patterns PR1 and PR2 having a smaller width. Accordingly, each of a distance between the source/drain via 180 and the gate electrode 120 adjacent to one another and a distance between the gate via 190 and the source/drain contact 160 adjacent to one another may be improved and/or increased. Accordingly, a short margin may be secured between the gate electrode 120 and the source/drain via 180 and between the source/drain contact 160 and the gate via 190. In addition, since the first via trench 180T and the second via trench 190T are formed by removing the third film 173, the width of each of the first via trench 180T and the second via trench 190T may be compensated for.

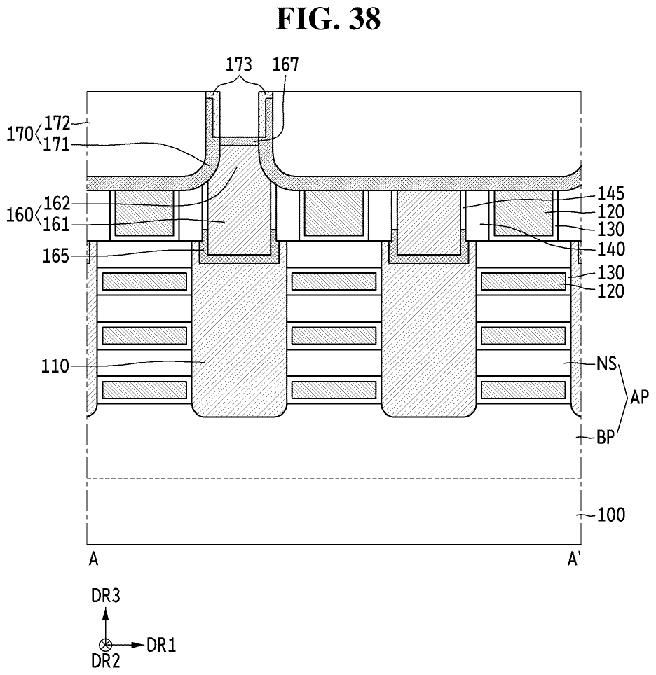

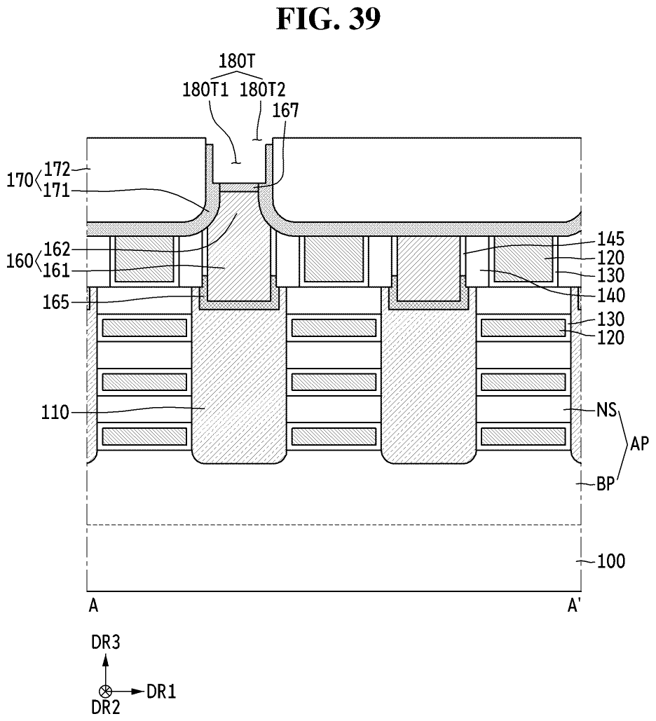

FIGS. 38 and 39 are diagrams of intermediate structures corresponding to intermediate steps of a method for manufacturing a semiconductor device according to some embodiments. FIG. 38 may be a manufacturing process performed after FIG. 18.

Referring to FIG. 38, plasma treatment may be performed on the portion of the first film 171 exposed through the second trench T2 to form the third film 173. The third film 173 may include a material different from that of each of the first film 171 and the second film 172. The upper surface and a portion of a side surface of the first film 171 may be converted to the third film 173 under the plasma treatment. The third film 173 may include a portion extending in each of the first direction DR1 and the second direction DR2 and a portion extending in the third direction DR3. The third film 173 may overlap the first film 171 in the first direction DR1.

Depending on a thickness of the first film 171, the third film 173 may be formed on an upper surface of the first film 171 as shown in FIG. 18, or the third film 173 may be formed on an upper surface and a side surface of the first film 171 as shown in FIG. 38.

Referring to FIG. 39, the third film (173 of FIG. 38) may be removed to form the first via trench 180T including the first lower trench 180T1 and the first upper trench 180T2.

Referring to FIG. 34, the source/drain via 180 may be formed to fill the second interlayer insulating film 195 and the first via trench 180T.

29

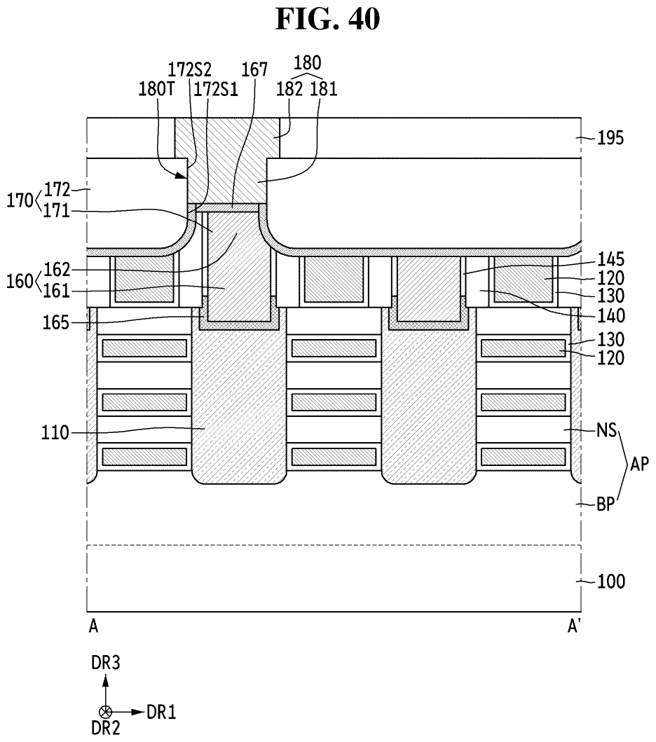

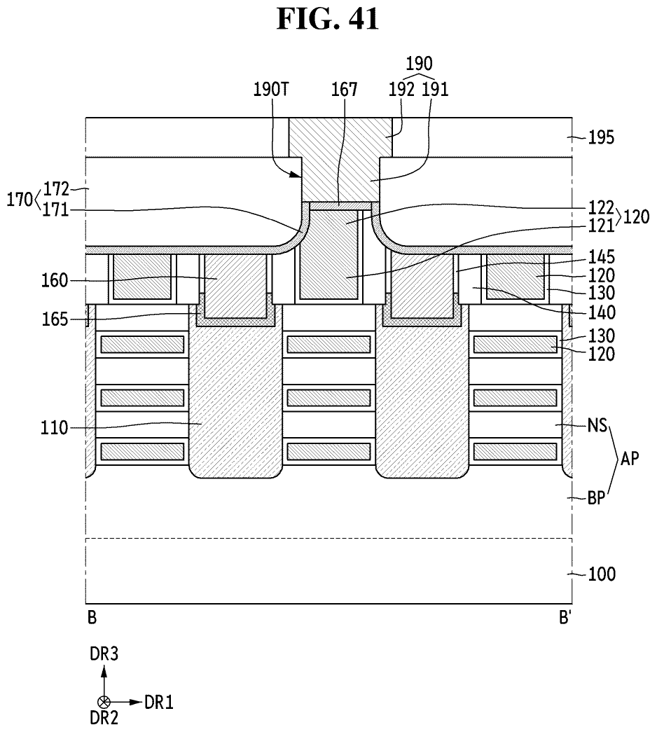

FIGS. 40 and 41 are diagrams for illustrating a semiconductor device according to some embodiments. For convenience of description, differences thereof from those described above with reference to FIGS. 1 to 5 will be mainly described.

Referring to FIG. 40, in the semiconductor device according to some embodiments, at least one of both opposing sidewalls in the first direction DR1 of the second portion 162 of the source/drain contact 160 may be spaced apart from the isolation insulating film 170. For example, one sidewall of both opposing sidewalls in the first direction DR1 of the second portion 162 of the source/drain contact 160 may be in contact with the isolation insulating film 170, and the other sidewall thereof may be spaced apart from the isolation insulating film 170 and may be in contact with the source/drain etch stop film 145. In other words, at least one of both opposing sidewalls in the first direction DR 1 of the first film 171 of the isolation insulating film 170 may be in contact with the gate spacer 140, and the other sidewall thereof may be in contact with the second portion 162 of the source/drain contact 160. Unlike the illustrated example, each of both opposing sidewalls in the first direction DR1 of the second portion 162 of the source/drain contact 160 may be spaced apart from the isolation insulating film 170 and may be in contact with the source/drain etch stop film 145. Each of both opposing sidewalls in the first direction DR1 of the first film 171 of the isolation insulating film 170 may be in contact with the gate spacer 140.

Referring to FIG. 41, in the semiconductor device according to some embodiments, at least one of both opposing sidewalls in the first direction DR1 of the second portion 122 of the gate electrode 120 may be spaced apart from the isolation insulating film 170. For example, one sidewall of both opposing sidewalls in the first direction DR1 of the second portion 122 of the gate electrode 120 may be in contact with the isolation insulating film 170, and the other sidewall thereof may be spaced apart from the isolation insulating film 170 and may be in contact with the gate insulating film 130. In other words, at least one of both opposing sidewalls in the first direction DR1 of the first film 171 of the isolation insulating film 170 may be in contact with the gate spacer 140, and the other sidewall thereof may be in contact with the second portion 122 of the gate electrode 120. Unlike the illustrated example, each of both opposing sidewalls in the first direction DR1 of the second portion 122 of the gate electrode 120 may be spaced apart from the isolation insulating film 170 and may be in contact with the gate insulating film 130. Each of both opposing sidewalls in the first direction DR1 of the first film 171 of the isolation insulating film 170 may be in contact with the gate spacer 140.

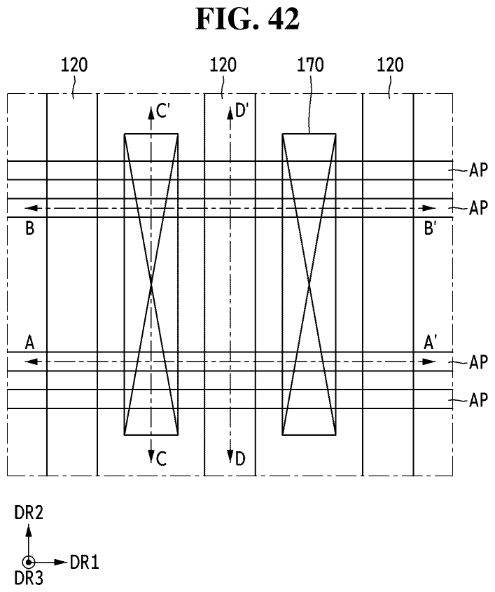

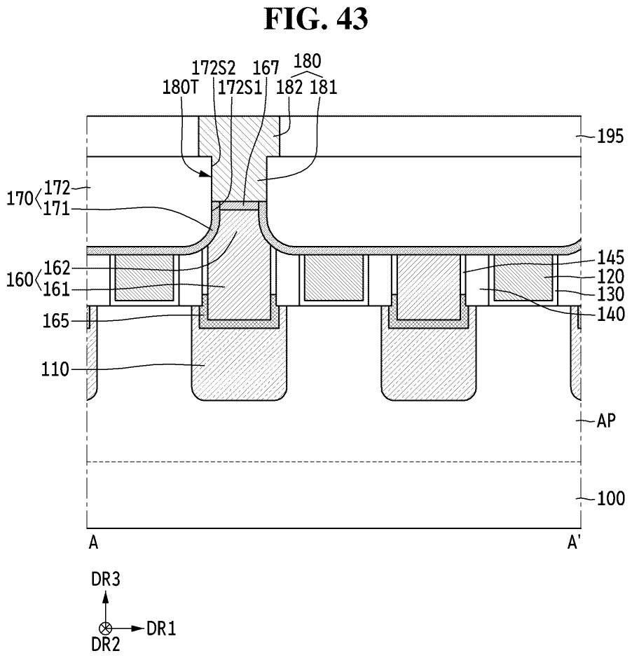

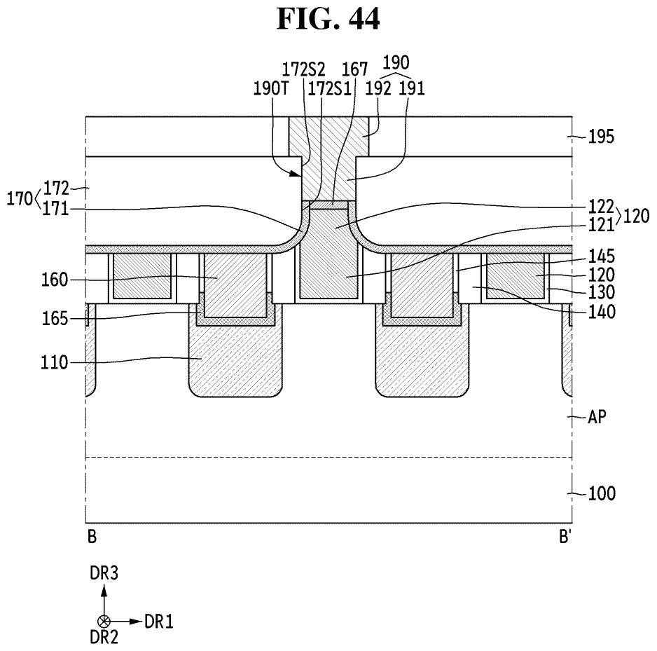

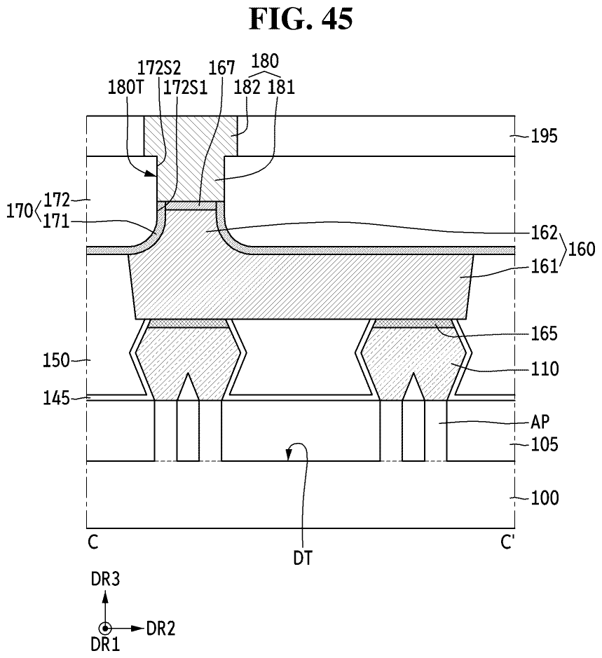

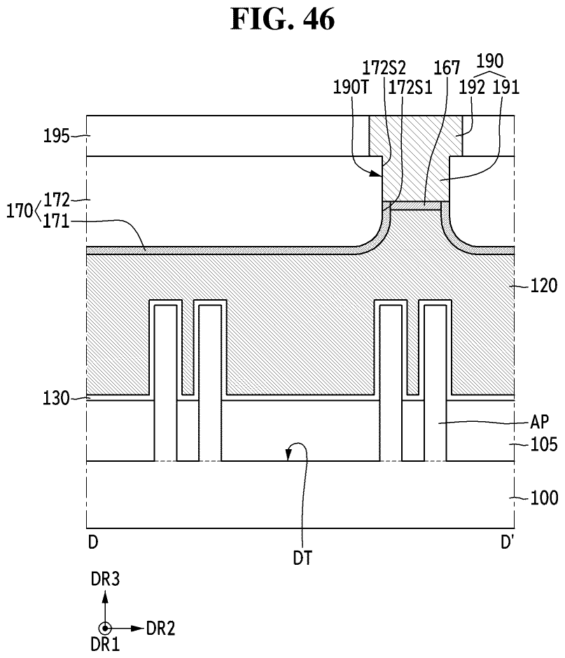

FIG. 42 is an example layout diagram for illustrating a semiconductor device according to some embodiments. FIG. 43 is a cross-sectional view taken along a line A-A′ of FIG. 42. FIG. 44 is a cross-sectional view taken along a line B-B′ of FIG. 42. FIG. 45 is a cross-sectional view taken along a line C-C′ of FIG. 42. FIG. 46 is a cross-sectional view taken along a line D-D′ of FIG. 42. For convenience of description, differences thereof from those described above with reference to FIGS. 1 to 5 will be mainly described.

Referring to FIGS. 42 to 46, in the semiconductor device according to some embodiments, the active pattern AP may be a fin type pattern protruding upwardly from the upper surface of the field insulating film 105. The field insulating layer 105 may surround a portion of a sidewall of the active pattern AP. The active patterns AP may be isolated from one another via a fin trench FT extending in an elongate manner in the second direction DR2. The source/drain pattern 110 may be disposed on the active pattern AP. The source/drain pattern 110 may be in contact with the active pattern AP.

According to embodiments of the present disclosure, there is provided a method for manufacturing a semiconductor device including forming a gate electrode on a substrate; forming a source/drain pattern on one side of the gate electrode; forming a source/drain contact on the source/drain pattern; forming a conductive film on the gate electrode and the source/drain contact; forming a photoresist pattern on a portion of the conductive film disposed on the source/drain contact; etching a portion of the gate electrode using the photoresist pattern to form a first trench; forming a first film extending along the first trench and forming a second film on the first film, wherein the first and second films include different materials; removing the photoresist pattern to form a second trench; performing a plasma treatment on a portion of the first film exposed through the second trench to form a third film; removing the third film to form a via trench; and forming a source/drain via filling the via trench.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. A semiconductor device comprising:
active patterns extending in a first direction and spaced apart from one another in a second direction;
a gate electrode on the active patterns and extending in the second direction;
a source/drain pattern on at least one side of the gate electrode;
a source/drain contact on the source/drain pattern;
an isolation insulating film on the gate electrode and the source/drain contact; and
a source/drain via in the isolation insulating film and on the source/drain contact,
wherein the isolation insulating film includes a first film and a second film on the first film, wherein the first film and the second film include different materials, and
wherein the first film extends along and on a bottom surface and a lower portion of a sidewall of the second film, and does not extend along and on an upper portion of the sidewall of the second film.

2. The semiconductor device of claim 1, wherein a sidewall of the source/drain via is in contact with the upper portion of the sidewall of the second film.

3. The semiconductor device of claim 1, wherein a sidewall of the source/drain via is in contact with the first film and the second film.

4. The semiconductor device of claim 1, further comprising a conductive film between the source/drain contact and the source/drain via.

5. The semiconductor device of claim 1, wherein a portion of a bottom surface of the source/drain via is in contact with the first film.

6. The semiconductor device of claim 1, wherein at least one of a first sidewall and a second sidewall of the source/drain contact opposite to one another in the first direction contacts the first film.

7. The semiconductor device of claim 1, wherein at least one of a first sidewall and a second sidewall of the source/drain contact opposite to one another in the first direction is spaced apart from the first film.

8. The semiconductor device of claim 1, further comprising a gate via in the isolation insulating film and on the gate electrode,
wherein a sidewall of the gate via is in contact with the second film.

9. The semiconductor device of claim 1, further comprising a gate via in the isolation insulating film and on the gate electrode,
wherein a sidewall of the gate via is in contact with the first film and the second film.

10. The semiconductor device of claim 1, further comprising:
a gate via in the isolation insulating film and on the gate electrode: and
a conductive film between the gate electrode and the gate via.

11. The semiconductor device of claim 1, wherein the first film includes silicon oxycarbide, and the second film includes silicon nitride.

12. The semiconductor device of claim 1, wherein the first film includes silicon, and the second film includes silicon oxide.

13. A semiconductor device comprising:
active patterns extending in a first direction and spaced apart from one another in a second direction;
a gate electrode on the active patterns and extending in the second direction;
a source/drain pattern on at least one side of the gate electrode;
a source/drain contact on the source/drain pattern;
an isolation insulating film on the gate electrode and the source/drain contact; and
a source/drain via in the isolation insulating film and on the source/drain contact,
wherein the isolation insulating film is partially intruded into the source/drain contact.

14. The semiconductor device of claim 13, further comprising a gate via disposed in the isolation insulating film and on the gate electrode,
wherein the isolation insulating film is partially intruded into the gate electrode.

15. The semiconductor device of claim 13, wherein the isolation insulating film includes a first film and a second film.

16. The semiconductor device of claim 13, further comprising a gate spacer on each of both opposing sidewalls of the gate electrode,
wherein the isolation insulating film is partially intruded into the gate spacer.

17. A semiconductor device comprising:
active patterns extending in a first direction and spaced apart from one another in a second direction;
a gate electrode on the active pattern and extending in the second direction;
a source/drain pattern on at least one side of the gate electrode;
a source/drain contact on the source/drain pattern;
an isolation insulating film on the gate electrode and the source/drain contact;
a source/drain via in the isolation insulating film and on the source/drain contact; and
a gate via in the isolation insulating film and on the gate electrode,
wherein the isolation insulating film includes a first film and a second film disposed on the first film,
wherein at least a portion of a bottom surface of the source/drain via and at least a portion of a bottom surface of the gate via are in contact with the first film.

18. The semiconductor device of claim 17, wherein the source/drain contact includes a first portion extending in the second direction and a second portion protruding from the first portion in a third direction,
wherein a sidewall of the second portion is in contact with the isolation insulating film,
wherein the source/drain via is on the second portion.

19. The semiconductor device of claim 17, wherein the gate electrode includes a first portion extending in the second direction and a second portion protruding from the first portion in a third direction,
wherein a sidewall of the second portion is in contact with the isolation insulating film,
wherein the gate via is disposed on the second portion of the gate electrode.

20. The semiconductor device of claim 17, wherein the first film and the second film of the isolation insulating film include different materials.
